(19) United States
(12) Patent Application Publication
(10) Pub. No.: US 2025/0192007 A1
(43) Pub. Date: Jun. 12, 2025

(54) SEMICONDUCTOR DEVICE

(71) Applicant: ROHM CO., LTD., Kyoto-shi (JP)

(72) Inventor: Kenichi YOSHIMOCHI, Kyoto-shi, Kyoto (JP)

(21) Appl. No.: 19/058,367

(22) Filed: Feb. 20, 2025

Related U.S. Application Data
(63) Continuation of application No. PCT/JP2023/027915, filed on Jul. 31, 2023.

(30) Foreign Application Priority Data
Aug. 22, 2022 (JP) 2022-131757

(51) Int. Cl. H01L 23/495; H01L 23/00

(52) U.S. Cl. CPC H01L 23/49562; H01L 24/48; H01L 2224/48137; H01L 2924/13064; H01L 2924/30107

(57) ABSTRACT

A semiconductor device includes: a first switching element having a first obverse surface oriented toward a first side in a thickness direction; a wiring layer disposed on the first side in the thickness direction with respect to the first switching element; and a second switching element disposed on the first side in the thickness direction with respect to the wiring layer. The first semiconductor element includes a first electrode, a second electrode, and a third electrode each formed on the first obverse surface. The second semiconductor element overlaps with the first semiconductor element as viewed in in the thickness direction. The second semiconductor element is electrically connected to the first semiconductor element via the wiring layer.

### TECHNICAL FIELD

The present disclosure relates to semiconductor devices.

### BACKGROUND ART

JP-A-2020-188085 discloses an example of a semiconductor device with laterally structured semiconductor elements (HEMTs). The semiconductor device of JP-A-2020-188085 includes a first semiconductor element, a second semiconductor element, and a control element. The first and second semiconductor elements are laterally structured switching elements (HEMTs). The control element controls the driving of the first and second semiconductor elements. The first semiconductor element, the second semiconductor element, and the control element are mounted on a lead frame and spaced apart from each other on the same plane (the plane containing the x and y directions shown in FIGS. 1 and 2 of the document).

The conventional semiconductor device described above is relatively large in plan view because the plurality of elements (the first and second semiconductor elements and the control element) are arranged on the same plane. This is not desirable for providing compact semiconductor devices. For the conventional semiconductor device, in addition, the conductive paths (wires) are relatively long because they need to connect the elements that are spaced apart along the same plane. This causes an increase in the parasitic inductance in the wires of the semiconductor device.

### BRIEF DESCRIPTION OF THE DRAWINGS

FIG. 1 is a plan view of a semiconductor device according to a first embodiment of the present disclosure.

FIG. 2 is a plan view of the semiconductor device according to the first embodiment of the present disclosure, with a sealing part shown as transparent.

FIG. 3 is a plan view corresponding to FIG. 2, omitting a switching element (second semiconductor element), a control element (a third semiconductor element), and portions of interconnect wirings.

FIG. 4 is a bottom view of the semiconductor device according to the first embodiment of the present disclosure.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a sectional view taken along line IX-IX in FIG. 2.

FIG. 10 is a sectional view taken along line X-X in FIG. 2.

FIG. 11 is a sectional view of a semiconductor device according to a first variation of the first embodiment, along the same line as FIG. 5.

FIG. 12 is a plan view of a semiconductor device according to a second embodiment of the present disclosure.

FIG. 13 is a sectional view taken along line XIII-XIII in FIG. 12.

FIG. 14 is a sectional view taken along line XIV-XIV in FIG. 12.

FIG. 15 is a sectional view taken along line XV-XV in FIG. 12.

FIG. 16 is a sectional view taken along line XVI-XVI in FIG. 12.

FIG. 17 is a sectional view of a semiconductor device according to a first variation of the second embodiment, taken along the same line as FIG. 14.

FIG. 18 is a plan view of a semiconductor device according to a third embodiment of the present disclosure.

FIG. 19 is a sectional view taken along line XIX-XIX in FIG. 18.

FIG. 20 is a sectional view taken along line XX-XX in FIG. 18.

FIG. 21 is a sectional view taken along line XXI-XXI in FIG. 18.

FIG. 22 is a sectional view taken along line XXII-XXII in FIG. 18.

FIG. 23 is a sectional view taken along line XXIII-XXIII in FIG. 18.

### DETAILED DESCRIPTION OF EMBODIMENTS

The following specifically describes preferred embodiments of the present disclosure with reference to the drawings.

In the present disclosure, the terms such as “first”, “second”, “third”, and so on are used merely as labels to identify the items referred to by the terms and are not intended to imply a specific order or sequence of such items.

In the description of the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Still further, “A surface A faces in a direction B (or is oriented toward a first side or an opposite second side in the direction B) is not limited, unless otherwise specifically noted, to the situation where the surface A forms an angle of 90° with the direction B but includes the situation where the surface A is inclined relative to the direction B.

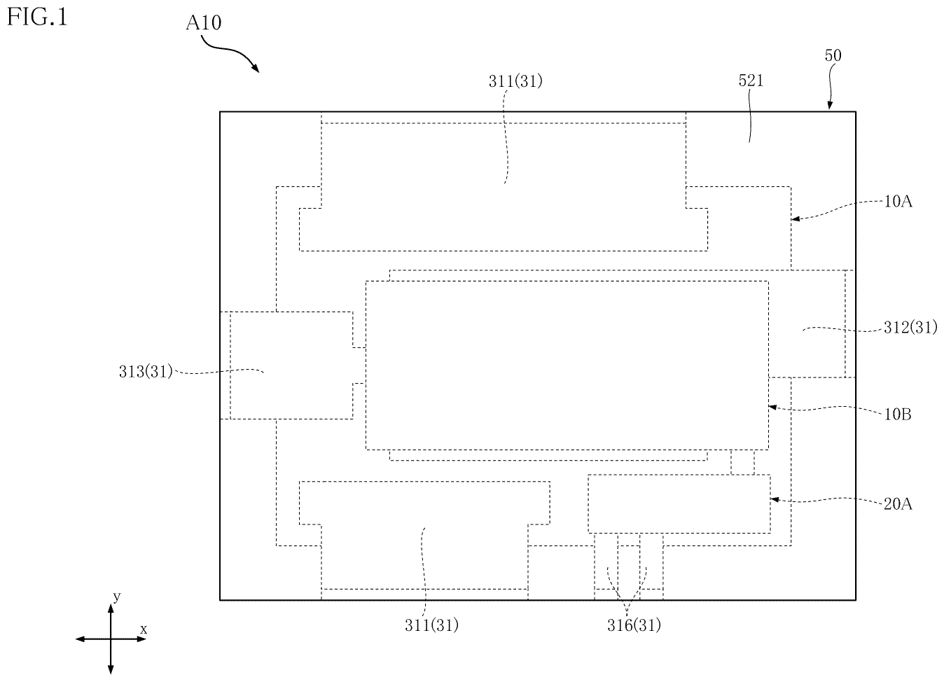

FIGS. 1 to 10 show a semiconductor device according to a first embodiment of the present disclosure. The semiconductor device A10 of the present embodiment includes a switching element 10A, a switching element 10B, a control element 20A, a wiring layer 31, a plurality of interconnect wirings 34, a plurality of communication wirings 35, a plurality of terminals 40, and a sealing part 50. The semiconductor device A10 is a resin packaged device for surface mounting on a circuit board.

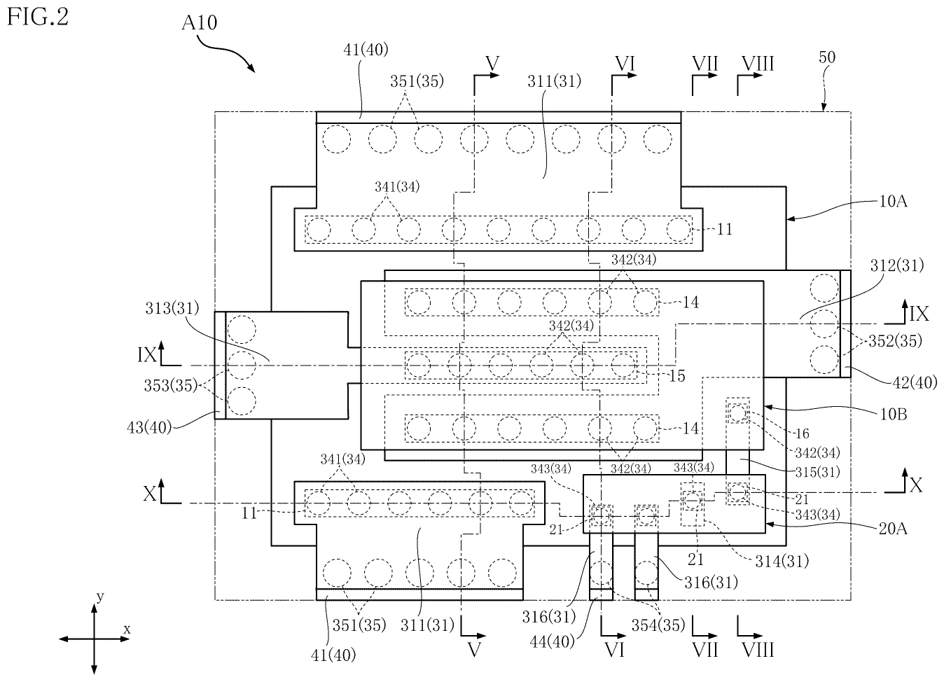

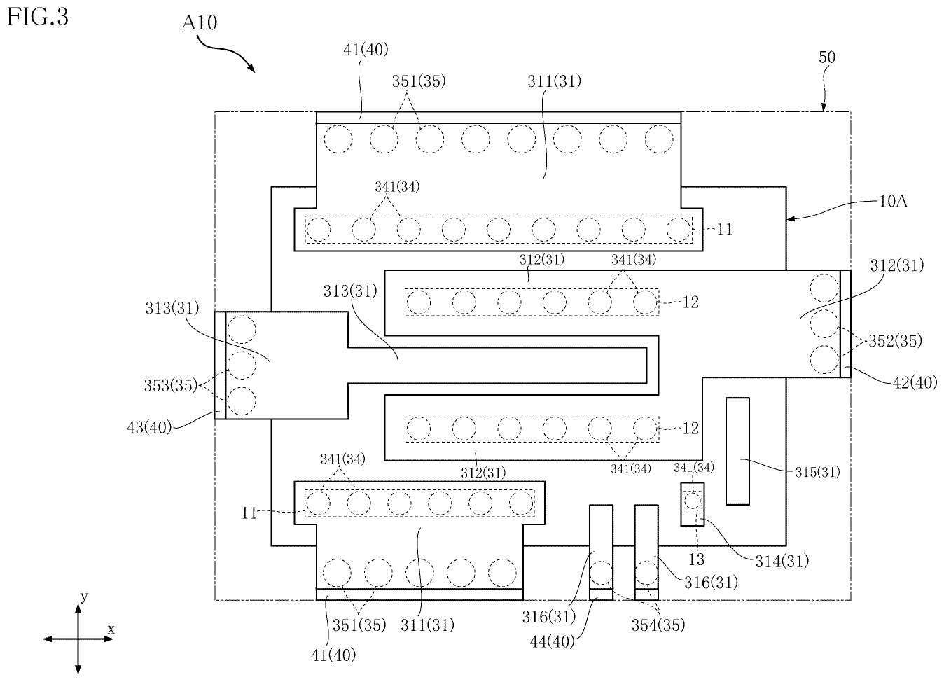

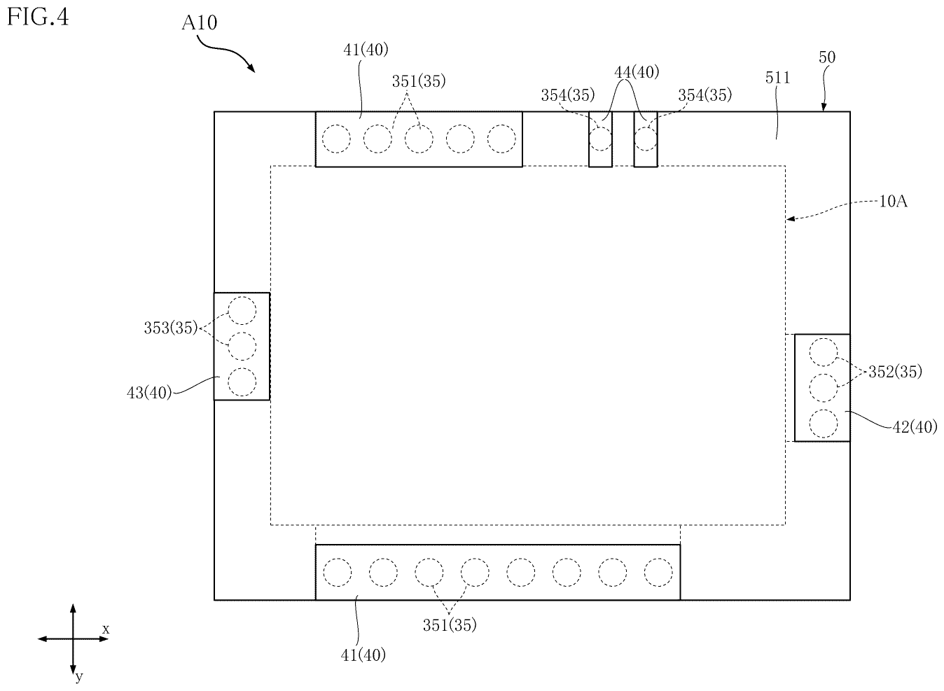

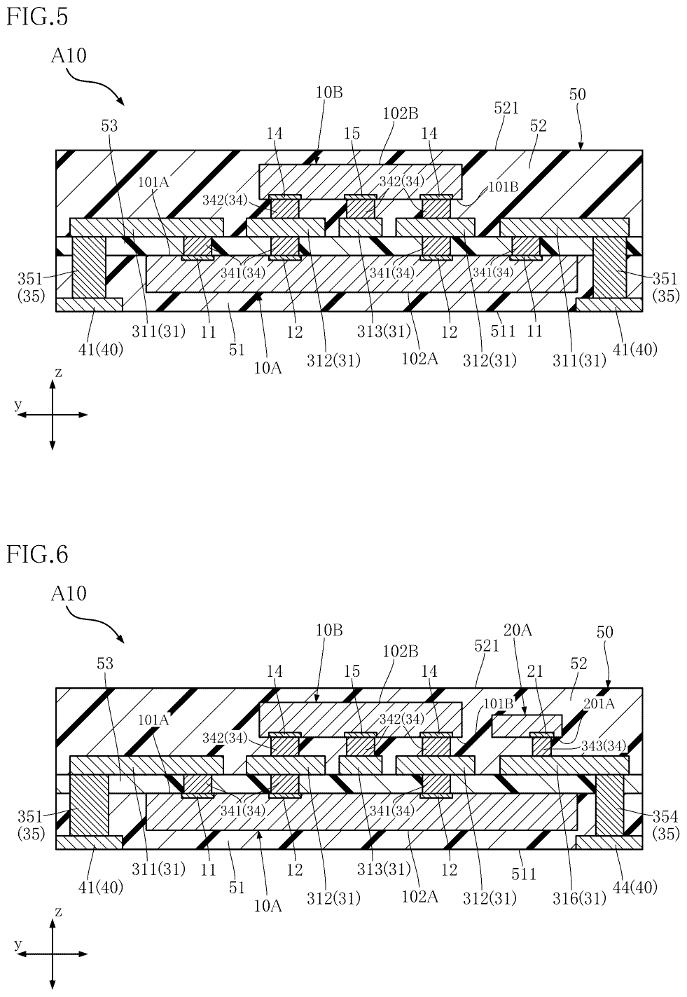

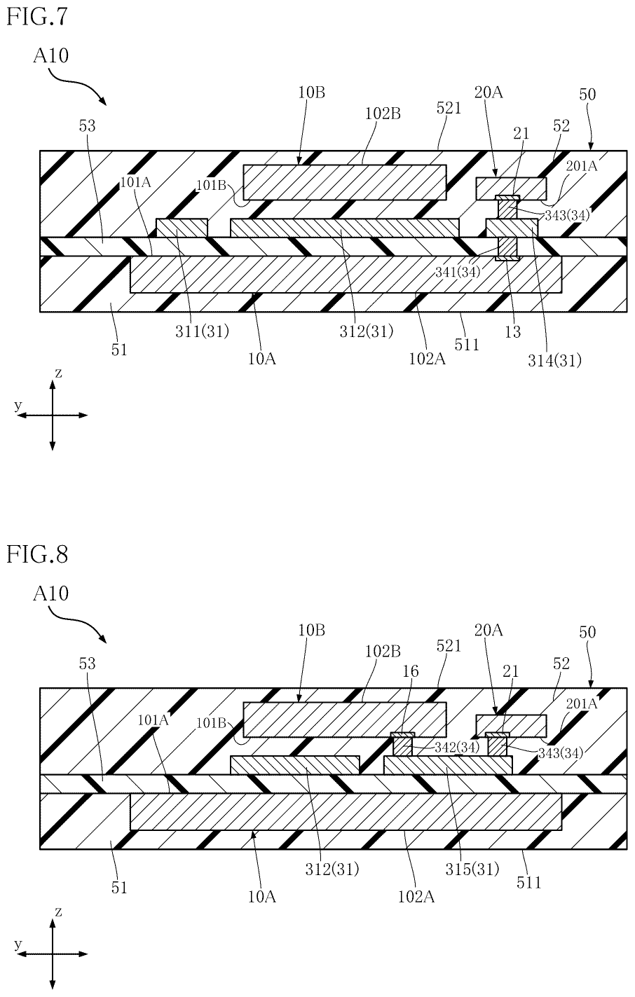

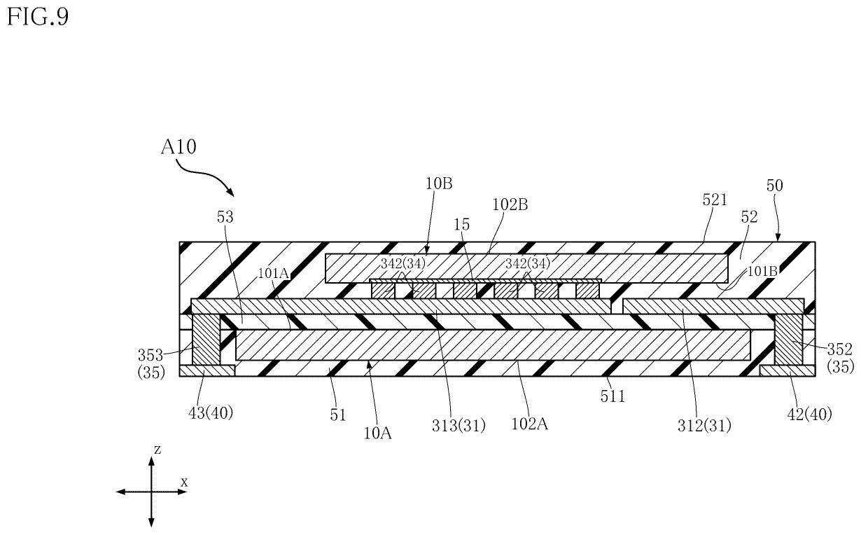

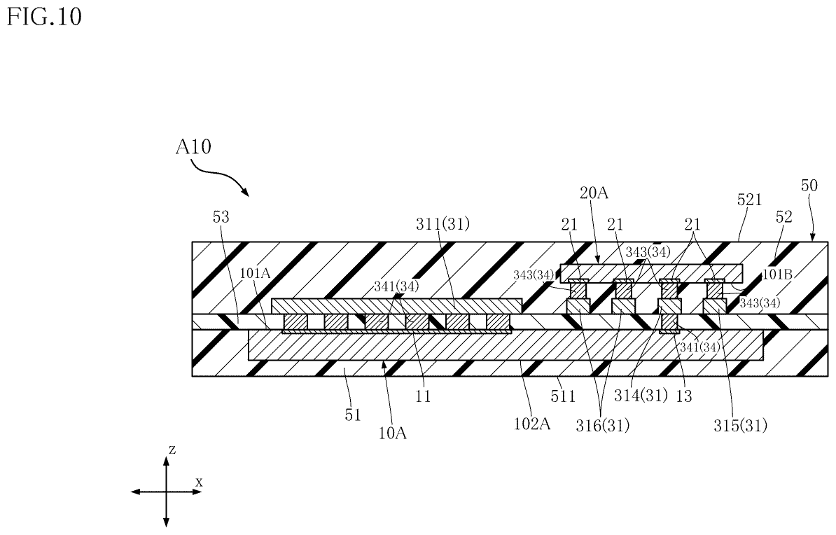

FIG. 1 is a plan view of the semiconductor device A10. FIG. 2 is another plan view of the semiconductor device A10. In FIG. 2, the sealing part 50 is shown as transparent and the outline of the sealing part 50 is indicated with an imaginary line (dash-double dot line). FIG. 3 is a plan view of the semiconductor device A10, similar to FIG. 2 but omitting the switching element 10B, the control element 20A, and the portions of the interconnect wirings 34 that are connected to the switching element 10B and the control element 20A. FIG. 4 is a bottom view of the semiconductor device A10. FIG. 5 is a sectional view taken along line V-V in FIG. 2. FIG. 6 is a sectional view taken along line VI-VI in FIG. 2. FIG. 7 is a sectional view taken along line VII-VII in FIG. 2. FIG. 8 is a sectional view taken along line VIII-VIII in FIG. 2. FIG. 9 is a sectional view taken along line IX-IX in FIG. 2. FIG. 10 is a sectional view taken along line X-X in FIG. 2.

The following description includes the references to mutually perpendicular directions, namely a thickness direction z, a first direction x, and a second direction y. The thickness direction z corresponds to the thickness direction of the semiconductor device A10. The phrase “in plan view” refers to a view as seen in the thickness direction z. The first direction x is perpendicular to the thickness direction z. The second direction y is perpendicular to both the thickness direction z and the first direction x. A first side in the thickness direction z is referred to as the a z1 side in the thickness direction z, and a second side as the z2 side in the thickness direction z. The z1 side in the thickness direction z may also be referred to as the upper side, and the z2 side as the lower side. The terms such as “top”, “bottom”, “above”, “below”, “upper surface”, and “lower surface”, are used to describe the relative positions of elements, and not necessarily describe their positions with respect to the direction of gravity. The semiconductor device A10 is rectangular as viewed in the thickness direction z.

The semiconductor device A10 converts an external supply of direct current power into alternating current power using the switching elements 10A and 10B. The semiconductor device A10 may be used in an inverter that drives a motor, for example. For the semiconductor device A10, the wiring structure including the wiring layer 31 and the interconnect wiring 34 can be formed using, for example, the redistribution layer (RDL) technology, which involves patterning and plating.

The sealing part 50 covers at least a portion of each of the switching elements 10A and 10B, the control element 20A, the wiring layer 31, the interconnect wirings 34, the communication wirings 35, and a portion of each terminal 40. The sealing part 50 may include an insulating resin material. The sealing part 50 is rectangular as viewed in the thickness direction z.

In the present embodiment, the sealing part 50 includes a first sealing part 51, a second sealing part 52, and a third sealing part 53. The first sealing part 51 is a portion of the sealing part 50 that is located on the z2 side in the thickness direction z. The first sealing part 51 has a bottom surface 511. The bottom surface 511 is oriented toward the z2 side in the thickness direction z. When the semiconductor device A10 is mounted on a circuit board, the bottom surface 511 faces the circuit board.

The second sealing part 52 is located on the z1 side in the thickness direction z with respect to the first sealing part 51. The second sealing part 52 has a top surface 521. The top surface 521 faces away from the bottom surface 511 in the thickness direction z (oriented toward the z1 side in the thickness direction z). The third sealing part 53 is located between the first sealing part 51 and the second sealing part 52 in the thickness direction z. The third sealing part 53 is in contact with both the first sealing part 51 and the second sealing part 52.

The switching elements 10A and 10B are transistors (switching elements) mainly used for power conversion. The switching elements 10A and 10B are made of a material, such as nitride semiconductor. For the semiconductor device A10, the switching elements 10A and 10B are high electron mobility transistors (HEMTs) made of a material, such as gallium nitride (GaN).

As shown in FIGS. 2, 3, and 5 to 7, the switching element 10A has a first obverse surface 101A, a first reverse surface 102A, a plurality of (two) first electrodes 11, a plurality of (two) second electrodes 12, and a third electrode 13. The first obverse surface 101A is oriented toward the z1 side in the thickness direction z. The first reverse surface 102A is spaced apart from the first obverse surface 101A in the thickness direction z. The first reverse surface 102A faces away from the first obverse surface 101A (toward the z2 side in the thickness direction z). The first electrodes 11, the second electrodes 12, and the third electrode 13 are formed on the first obverse surface 101A.

As shown in FIGS. 2 and 3, the plurality of (two) first electrodes 11 and the plurality of (two) second electrodes 12 each extend in the first direction x. The two first electrodes 11 are located on opposite sides of the switching element 10A in the second direction y. The two second electrodes 12 are located between the two first electrodes 11 in the second direction y. The two second electrodes 12 are spaced apart from each other in the second direction y. The electric current corresponding to the power to be converted by the switching element 10A flows through the second electrodes 12. Thus, the second electrodes 12 each correspond to the drain of the switching element 10A. The electric current corresponding to the power converted by the switching element 10A flows through the first electrodes 11. Thus, the first electrodes 11 each correspond to the source of the switching element 10A.

As shown in FIG. 3, the location of the third electrode 13 in the switching element 10A is near the end in the first direction x and also near the end in the second direction y. The third electrode 13 receives a gate voltage that controls the drive of the switching element 10A. Thus, the third electrode 13 corresponds to the gate of the switching element 10A. As viewed in the thickness direction z, the third electrode 13 has a smaller area than each of the first and second electrodes 11 and 12. The switching element 10A is not limited to this example in terms of the shape, number, and arrangement of the first, second and third electrodes 11, 12, and 13, and various modifications are possible. The switching element 10A of the configuration described above is an example of the “first semiconductor element” of the present disclosure.

In the present embodiment, at least a portion of the switching element 10A is covered with the first sealing part 51. In the illustrated example, the switching element 10A is covered with the first sealing part 51, except for the first obverse surface 101A. That is, the first reverse surface 102A is covered with the first sealing part 51. The first obverse surface 101A is in contact with the third sealing part 53. The first, second and third electrodes 11, 12, and 13 face the third sealing part 53.

As shown in FIGS. 5 to 9, the switching element 10B is located on the z1 side in the thickness direction z with respect to the switching element 10A. The switching element 10B overlaps with the switching element 10A as viewed in the thickness direction z. As shown in FIG. 2, the switching element 10B has a smaller area than the switching element 10A as viewed in the thickness direction z.

As shown in FIGS. 2, 5, 8, and 9, the switching element 10B has a second obverse surface 11B, a second reverse surface 102B, a plurality of (two) fourth electrodes 14, a fifth electrode 15, and a sixth electrode 16. The second obverse surface 101B is oriented toward the z2 side in the thickness direction z. The second obverse surface 101B faces the first obverse surface 101A of the switching element 10A. The second reverse surface 102B is spaced apart from the second obverse surface 101B in the thickness direction z. The second reverse surface 102B faces away from the second obverse surface 101B (toward the z1 side in the thickness direction z). The fourth electrodes 14, the fifth electrode 15, and the sixth electrode 16 are formed on the second obverse surface 1B.

As shown in FIGS. 2 and 9, the plurality of (two) fourth electrodes 14 and the fifth electrode 15 each extend in the first direction x. The two fourth electrodes 14 are disposed on opposite sides of the switching element 10B in the second direction y. As can be understood from FIGS. 2, 3, 5, and 6, the two fourth electrodes 14 respectively overlap with the two second electrodes 12 of the switching element 10A as viewed in the thickness direction z. The fifth electrode 15 is located between the two fourth electrodes 14 in the second direction y. The electric current corresponding to the power to be converted by the switching element 10B flows through the fifth electrode 15. Thus, the fifth electrode 15 corresponds to the drain of the switching element 10B.

The electric current corresponding to the power converted by the switching element 10B flows through the fourth electrodes 14. Thus, the fourth electrodes 14 each correspond to the source of the switching element 10B.

As shown in FIG. 2, the location of the sixth electrode 16 in the switching element 10B is near the end in the first direction x and also near the end in the second direction y. The sixth electrode 16 receives a gate voltage that controls the drive of the switching element 10B. Hence, the sixth electrode 16 corresponds to the gate of the switching element 10B. As viewed in the thickness direction z, the sixth electrode 16 has a smaller area than each of the fourth and fifth electrodes 14 and 15. As shown in FIGS. 5 and 6 in particular, the switching element 10B is electrically connected to the switching element 10A via the wiring layer 31. The switching element 10B is not limited to this example in terms of the shape, number, and arrangement of the fourth, fifth, and sixth electrodes 14, 15, and 16, and various modifications are possible. The switching element 10B of the configuration described above is an example of the “second semiconductor element” of the present disclosure.

In the present embodiment, at least a portion of the switching element 10B is covered with the second sealing part 52. In the illustrated example, the entire switching element 10B is covered with the second sealing part 52.

The semiconductor device A10 is formed as a half-bridge switching circuit, for example. In this case, the switching element 10B forms the upper arm circuit of the semiconductor device A10, and the switching element 10A forms the lower arm circuit. The switching elements 10B and 10A are connected in series.

As shown in FIGS. 6 to 8, and 10, the control element 20A is located on the z1 side in the thickness direction z with respect to the switching element 10A. The control element 20A overlaps with the switching element 10A as viewed in the thickness direction z. As shown in FIG. 2, the control element 20A has a smaller area than each of the switching elements 10A and 10B as viewed in the thickness direction z.

The control element 20A is electrically connected to the switching elements 10A and 10B. The control element 20A is a gate driver that applies gate voltage to the third electrode 13 of the switching element 10A and the sixth electrode 16 of the switching element 10B.

As shown in FIGS. 2, 6 to 8, and 10, the control element 20A has a third obverse surface 201A and a plurality of (four) pads 21. The third obverse surface 201A is oriented toward the z2 side in the thickness direction z. The third obverse surface 201A faces the first obverse surface 101A of the switching element 10A. The plurality of pads 21 are formed on the third obverse surface 201A. As shown in FIGS. 2, 6 to 8, and 10, each pad 21 is rectangular as viewed in the thickness direction. The control element 20A is not limited to this example in terms of the shape, number, and arrangement of the pads 21, and various modifications are possible. The control element 20A of the configuration described above is an example of the “third semiconductor element” of the present disclosure.

As shown in FIGS. 5 to 10, the wiring layer 31 is located between the switching element 10A and each of the switching element 10B and the control element 20A in the thickness direction z. Hence, the wiring layer 31 is located on the z1 side in the thickness direction z with respect to the switching element 10A. The switching element 10B and the control element 20A are located on the z1 side in the thickness direction z with respect to the wiring layer 31. The wiring layer 31 is located between the third sealing part 53 and the second sealing part 52. At least a portion of the wiring layer 31 is embedded in the second sealing part 52. The constituent material of the wiring layer 31 is not specifically limited and may include copper (Cu), for example.

As shown in FIGS. 2, 3, and 5 to 10, the wiring layer 31 includes a first wiring 311, a second wiring 312, a third wiring 313, a fourth wiring 314, a fifth wiring 315, and a control wiring 316. In the illustrated example, two first wirings 311 are disposed at two separate locations. The two first wirings 311 are located at the positions corresponding to the plurality of (two) first electrodes 11 of the switching element 10A. Each first wiring 311 overlaps with the corresponding first electrode 11 as viewed in the thickness direction z. As shown in FIGS. 5, 6, and 10, each first electrode 11 of the switching element 10A is electrically connected to the first wiring 311 via one of the interconnect wirings 34.

The second wiring 312 has a branched shape with two extending portions corresponding to the plurality of (two) second electrodes 12 of the switching element 10A and the plurality of (two) fourth electrodes 14 of the switching element 10B. The second wiring 312 overlaps with the second electrodes 12 and the fourth electrodes 14 as viewed in the thickness direction z. As shown in FIGS. 5 and 6, each second electrode 12 of the switching element 10A is electrically connected to the second wiring 312 via one of the interconnect wirings 34. Additionally, each fourth electrode 14 of the switching element 10B is electrically connected to the second wiring 312 via one of the interconnect wirings 34. That is, the fourth electrodes 14 of the switching element 10B are electrically connected to the second electrodes 12 of the switching element 10A via the wiring layer 31 (the second wiring 312).

The third wiring 313 is located at the position corresponding to the fifth electrode 15 of the switching element 10B. The third wiring 313 overlaps with the fifth electrode 15 as viewed in the thickness direction z. As shown in FIGS. 5, 6, and 9, the fifth electrode 15 is electrically connected to the third wiring 313 via one of the interconnect wirings 34.

The fourth wiring 314 is located at the position corresponding to the third electrode 13 of the switching element 10A and one of the pads 21 of the control element 20A. The fourth wiring 314 overlaps with the third electrode 13 and the pad 21 as viewed in the thickness direction z. As shown in FIGS. 7 and 10, the third electrode 13 is electrically connected to the fourth wiring 314 via one of the interconnect wirings 34. Also, the pad 21 is electrically connected to the fourth wiring 314 via one of the interconnect wirings 34. Thus, the control element 20A (the relevant pad 21) is electrically connected to the third electrode 13 via the fourth wiring 314. The pad 21 that is electrically connected to the third electrode 13 via the fourth wiring 314 overlaps with the third electrode 13 as viewed in the thickness direction z.

The fifth wiring 315 is located at the position corresponding to the sixth electrode 16 of the switching element 10B and one of the pads 21 of the control element 20A. The fifth wiring 315 overlaps with the sixth electrode 16 and the pad 21 as viewed in the thickness direction z. As shown in FIG. 8, the sixth electrode 16 is electrically connected to the fifth wiring 315 via one of the interconnect wirings 34. Also, the pad 21 is electrically connected to the fifth wiring 315 via one of the interconnect wirings 34. Thus, the control element 20A (the relevant pad 21) is electrically connected to the sixth electrode 16 via the fifth wiring 315.

The control wiring 316 is located at the position corresponding to one of the pads 21 of the control element 20A. In the illustrated example, two control wirings 316 are disposed at two separate locations. The two control wirings 316 are located at the positions corresponding to two pads 21 of the control element 20A. Each control wiring 316 overlaps with the relevant pad 21 as viewed in the thickness direction z. As shown in FIGS. 6 and 10, the two pads 21 are each electrically connected to the control wiring 316 via one of the interconnect wirings 34.

As shown in FIGS. 5 to 10, each interconnect wiring 34 is embedded in either the second sealing part 52 or the third sealing part 53. As shown in FIGS. 2 and 3, each interconnect wiring 34 overlaps with either the switching element 10A or 10B, or the control element 20A as viewed in the thickness direction z. Each interconnect wiring 34 is connected to the wiring layer 31 (either the first, second, third, fourth, or fifth wiring 311, 312, 313, 314, or 315, or the control wiring 316).

As shown in FIGS. 2, 3, and 5 to 10, the plurality of interconnect wirings 34 include a plurality of first interconnect wirings 341, a plurality of second interconnect wirings 342, and a plurality of third interconnect wirings 343.

As shown in FIGS. 5 to 7, and 10, the first interconnect wirings 341 are interposed between the switching element 10A and the wiring layer 31 in the thickness direction z. In the illustrated example, the first interconnect wirings 341 are embedded in the third sealing part 53. Each first interconnect wiring 341 is connected to one of the plurality of (two) first electrodes 11, the plurality of (two) second electrodes 12, and the third electrode 13 of the switching element 10A. The constituent material of the first interconnect wirings 341 is the same as that of the wiring layer 31, and examples include copper (Cu).

As shown in FIGS. 5, 6, 8, and 9, the second interconnect wirings 342 are interposed between the switching element 10B and the wiring layer 31 in the thickness direction z. In the illustrated example, the second interconnect wirings 342 are embedded in the second sealing part 52. Each second interconnect wiring 342 is connected to one of the plurality of (two) fourth electrodes 14, the fifth electrode 15, and the sixth electrode 16 of the switching element 10B. The constituent material of the second interconnect wirings 342 is not specifically limited. In one example, the second interconnect wirings 342 are made of a conductive bonding material, such as solder.

As shown in FIGS. 6 to 8, and 10, the third interconnect wirings 343 are interposed between the control element 20A and the wiring layer 31 in the thickness direction z. In the illustrated example, the third interconnect wirings 343 are embedded in the second sealing part 52. Each third interconnect wiring 343 is connected to one of the plurality of (four) pads 21 of the control element 20A. The constituent material of the third interconnect wirings 343 is not specifically limited. In one example, the third interconnect wirings 343 are made of a conductive bonding material, such as solder.

As shown in FIGS. 5, 6, and 9, the communication wirings 35 are embedded in the first sealing part 51 and the third sealing part 53. As shown in FIGS. 2, 3, 5, 6, and 9, each communication wiring 35 overlaps with the wiring layer 31 (one of the first, second, third, and control wirings 311, 312, 313, and 316) as viewed in the thickness direction z. As shown in FIGS. 5, 6, and 9, each communication wiring 35 is connected to the wiring layer 31 (either the first, second, or third wiring 311, 312, or 313, or the control wiring 316). The constituent material of the communication wirings 35 is the same as that of the wiring layer 31, and examples include copper (Cu).

As shown in FIGS. 2, 3, 5, 6 and 9, the plurality of communication wirings 35 include a plurality of first communication wirings 351, a plurality of second communication wirings 352, a plurality of third communication wirings 353, and a plurality of fourth communication wirings 354.

As shown in FIGS. 2, 3, 5, and 6, the plurality of first communication wirings 351 are connected to the first wiring 311 and a plurality of first terminals 41, which willbe described later.

As shown in FIGS. 2, 3, and 9, the plurality of second communication wirings 352 are connected to the second wiring 312 and a second terminal 42, which will be described later. As shown in FIGS. 2, 3, and 9, the plurality of third communication wirings 353 are connected to the third wiring 313 and a third terminal 43, which will be described later. As shown in FIGS. 2, 3, and 6, each fourth communication wiring 354 is connected to one of the plurality of (two) control wirings 316 and one of a plurality of control terminals 44, which will be described later.

As shown in FIGS. 5, 6, and 9, a portion of each terminal 40 is embedded in the first sealing part 51. The terminals 40 are located on the z1 side in the thickness direction z with respect to the first obverse surface 101A of the switching element 10A. The terminals 40 are exposed at the bottom surface 511 of the first sealing part 51. Each terminal 40 is connected to one of the communication wirings 35 (the first, second, third, and fourth communication wirings 351, 352, 353, and 354). Thus, each terminal 40 is electrically connected to either the switching element 10A or 10B, or the control element 20A via the wiring layer 31 (one of the first, second, third, and control wirings 311, 312, 313, and 316). The constituent material of the terminals 40 is the same as that of the wiring layer 31, and examples include copper (Cu).

As shown in FIGS. 2, 3, 5, 6, and 9, the plurality of terminals 40 include a plurality of (two) first terminals 41, a second terminal 42, a third terminal 43, and a plurality of (two) control terminals 44.

As shown in FIGS. 2, 3, and 5, each of the two first terminals 41 is electrically connected to the first wiring 311 via the first communication wirings 351. As shown in FIGS. 2, 3, and 9, the third terminal 43 is electrically connected to the third wiring 313 via the third communication wirings 353. The two first terminals 41 and the third terminal 43 are used to input direct current power that is to be converted by the switching elements 10A and 10B. The two first terminals 41 are negative terminals (N terminals). The third terminal 43 is a positive terminal (P terminal).

As shown in FIGS. 2, 3, and 9, the second terminal 42 is electrically connected to the second wiring 312 via the second communication wirings 352. The second terminal 42 outputs the alternating current power resulting from the conversion by the switching elements 10A and 10B.

The plurality of (two) control terminals 44 are each electrically connected to the control wiring 316 via one of the fourth communication wirings 354. Hence, each control terminal 44 is electrically connected to the control element 20A. One of the control terminals 44 receives the power for driving the control element 20A. One of the control terminals 44 receives an electrical signal directed to the control element 20A.

Unlike the illustrated example, a coating layer may be provided to cover the bottom surface 511 of the sealing part 50 (the first sealing part 51). Such a coating layer may be made of solder resist. In addition, the coating layer is formed with a plurality of openings. Each opening extends through the coating layer in the thickness direction z, exposing one of the terminals 40 to the outside. This allows the terminals 40 to be bonded and electrically connected to a circuit board by soldering, for example, when the semiconductor device A10 is mounted onto the circuit board. Providing such a coating layer may also apply to any of the variations and embodiments described below.

The following describes the operation of the present embodiment.

The semiconductor device A10 includes: the switching element 10A (the first semiconductor element); the wiring layer 31 located on the z1 side in the thickness direction z with respect to the switching element 10A; and the switching element 10B (the second semiconductor element) located on the z1 side in the thickness direction z with respect to the wiring layer 31. The switching element 10A has the first obverse surface 101A oriented toward the z1 side in the thickness direction z, and includes the first electrode 11, the second electrode 12, and the third electrode 13 formed on the first obverse surface 101A. The switching element 10A may be a lateral HEMT, for example. The switching element 10B is electrically connected to the switching element 10A via the wiring layer 31 and overlaps with the switching element 10A as viewed in the thickness direction z. With the plurality of elements, including the lateral switching element 10A, stacked in the thickness direction z, the plan-view size of the semiconductor device A10 (the size as viewed in the thickness direction z) is reduced. Thus, the overall size of the semiconductor device A10 can be reduced as well.

With the configuration described above, the conduction path between the elements (the switching elements 10A and 10B) can be shorter than in a configuration where the elements are arranged on the same plane. This helps to reduce the parasitic inductance caused by the internal interconnects of the semiconductor device A10.

The switching element 10B has the second obverse surface 101B and the fourth, fifth, and sixth electrodes 14, 15, and 16 formed on the second obverse surface 101B. The switching element 10B may be a lateral HEMT. The second obverse surface 101B is oriented toward the z2 side in the thickness direction z, facing the first obverse surface 101A of the switching element 10A. With this configuration, the conduction path is appropriately shorter between an electrode of the switching element 10A (the second electrode 12) and an electrode of the switching element 10B (the fourth electrode 14) that are electrically connected via the wiring layer 31 (the second wiring 312). This is desirable for reducing the internal parasitic inductance of the semiconductor device A10.

The wiring layer 31 includes the first wiring 311, the second wiring 312, and the third wiring 313. As shown in FIGS. 5 and 6, for the semiconductor device A10, the second electrodes 12 (the drain) of the switching element 10A (the lower arm) and the fourth electrodes 14 (the source) of the switching element 10B (the upper arm) are electrically connected to the second wiring 312. The fourth electrodes 14 overlap with the respective second electrodes 12 as viewed in the thickness direction z. In the illustrated example, the two fourth electrodes 14 overlap with the respective two second electrodes 12 as viewed in the thickness direction z. This configuration allows each second electrode 12 of the switching element 10A and the corresponding fourth electrode 14 of the switching element 10B to be connected by a conduction path that is substantially linear along the thickness direction z. This configuration is therefore more suitable for shortening the conduction path between the second electrode 12 and the fourth electrode 14, and thus reducing the internal parasitic inductance of the semiconductor device A10.

The semiconductor device A10 includes the control element 20A (the third semiconductor element) located on the z1 side in the thickness direction z with respect to the wiring layer 31.

The control element 20A overlaps with the switching element 10A (the first semiconductor element) as viewed in the thickness direction z. With this configuration, the semiconductor device A10 provided with the plurality of elements (including the lateral switching elements 10A and 10B, and the control element 20A) can be more compact in plan-view size (the size as viewed in the thickness direction z). Thus, the overall size of semiconductor device A10 can be reduced.

The wiring layer 31 includes the fourth wiring 314 and the fifth wiring 315. The control element 20A has the third obverse surface 201A oriented toward the z2 side in the thickness direction z and the plurality of pads 21 formed on the third obverse surface 201A. One of the pads 21 is electrically connected to the third electrode 13 (the gate) of the switching element 10A via the fourth wiring 314. One of the pads 21 is electrically connected to the sixth electrode 16 (the gate) of the switching element 10B via the fifth wiring 315. With this configuration, the conduction path is appropriately shorter between the third electrode 13 of the switching element 10A or the sixth electrode 16 of the switching element 10B and the relevant pad 21 of the control element 20A that are electrically connected via the wiring layer 31 (the fourth wiring 314 and the fifth wiring 315). This is desirable for reducing the internal parasitic inductance of the semiconductor device A10.

The following describes other embodiments and variations embodying a semiconductor device according to the present disclosure. The configurations of elements and components in each embodiment or variation may be combined in any manner, provided that no technical inconsistencies arise.

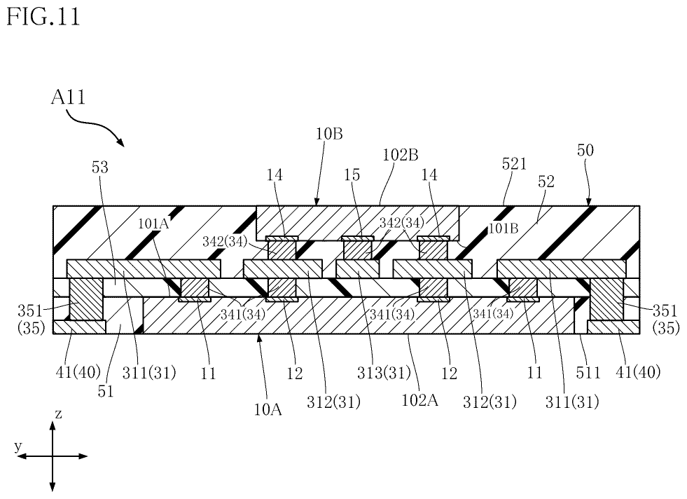

FIG. 11 shows a semiconductor device according to a first variation of the first embodiment. FIG. 11 is a sectional view of a semiconductor device A11 according to this variation, showing a section taken along the same line as FIG. 5 of the first embodiment. In FIG. 11 and subsequent figures, elements that are identical or similar to those of the semiconductor device A10 are indicated by the same reference numerals, and a relevant description is appropriately omitted.

For the semiconductor device A11 of this variation, the switching elements 10A and 10B respectively have a first reverse surface 102A and a second reverse surface 102B that are exposed from the sealing part 50. More specifically, the first reverse surface 102A of the switching element 10A is exposed from the first sealing part 51. In the illustrated example, the first reverse surface 102A of the switching element 10A is flush with the bottom surface 511 of the first sealing part 51. The second reverse surface 102B of the switching element 10B is exposed from the second sealing part 52. In the illustrated example, the second reverse surface 102B of the switching element 10B is flush with the top surface 521 of the second sealing part 52.

For the semiconductor device A11, the first reverse surface 102A of the switching element 10A is exposed from the first sealing part 51, and the second reverse surface 102B of the switching element 10B from the second sealing part 52. This configuration ensures that heat generated by the switching elements 10A and 10B is efficiently dissipated to the outside of the semiconductor device A11. Thus, the heat dissipation of the semiconductor device A11 is improved.

In the semiconductor device A11, the first reverse surface 102A is exposed from the first sealing part 51 (the sealing part 50) and thus can be bonded to a circuit board, for example. In addition, the second reverse surface 102B is exposed from the second sealing part 52 (the sealing part 50) and thus can be bonded to a heat dissipating member, for example. This helps to further improve the heat dissipation of the semiconductor device A11. In another variation not shown in the figures, the control element 20A may be configured such that its surface oriented toward the z1 side in the thickness direction z is exposed from the second sealing part 52 (the sealing part 50). This variation ensure that heat generated by the control element 20A is efficiently dissipated to the outside of the semiconductor device A11. The semiconductor device A11 additionally achieves the same operation and effects as those achieved by the semiconductor device A10.

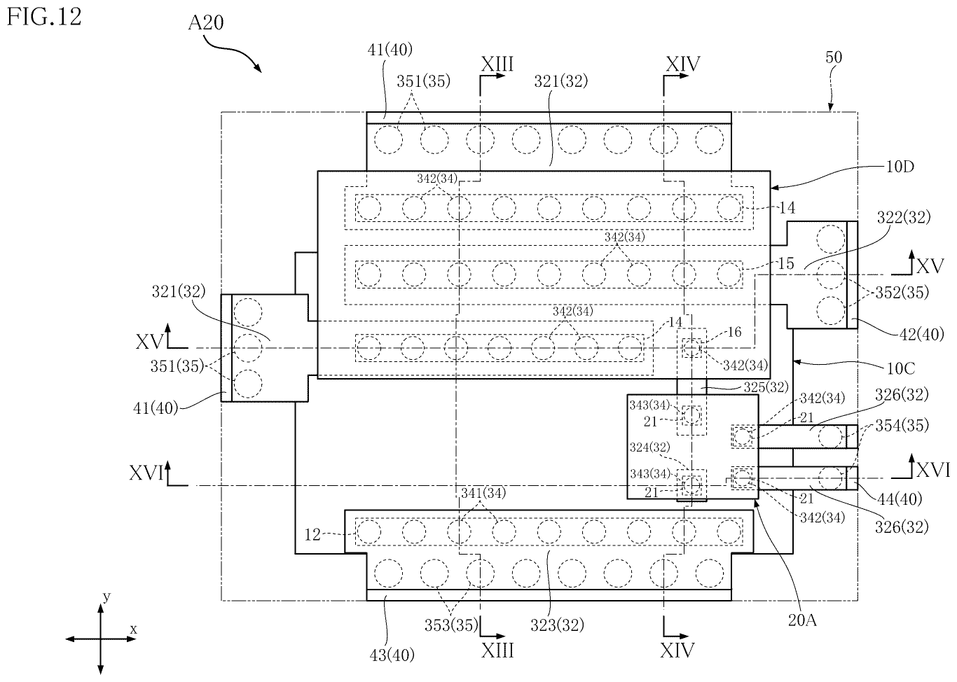

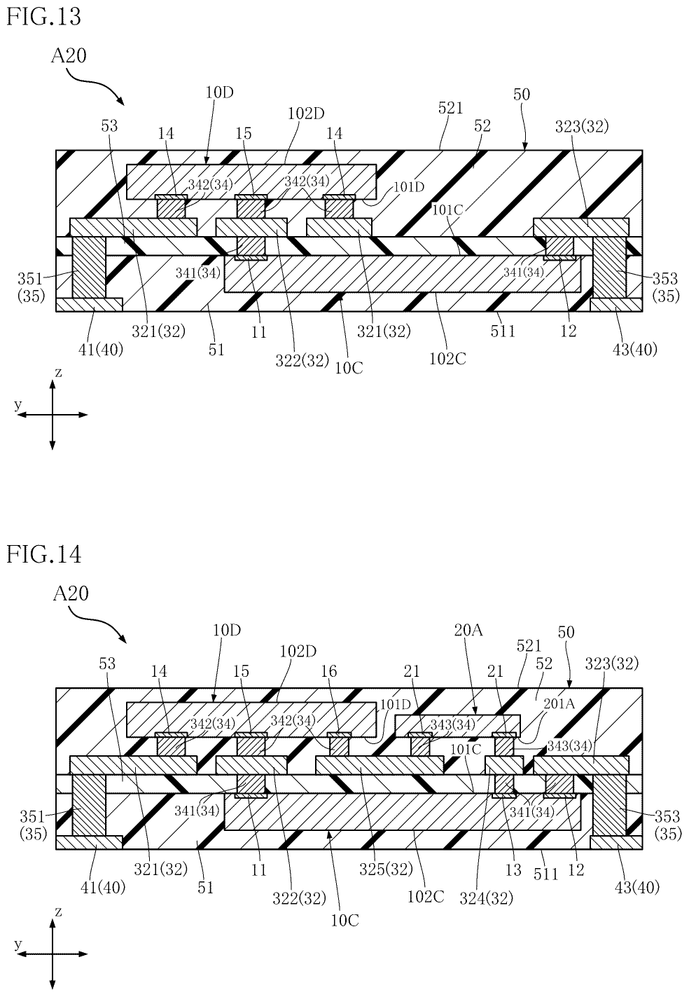

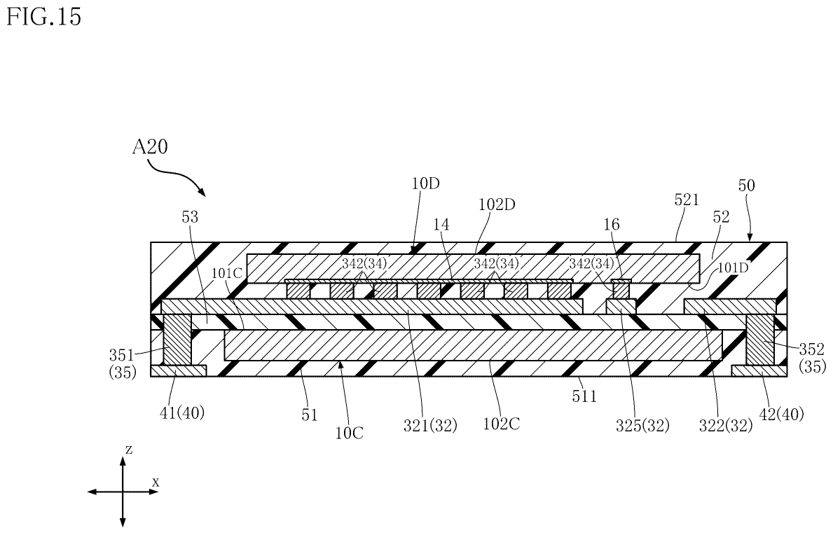

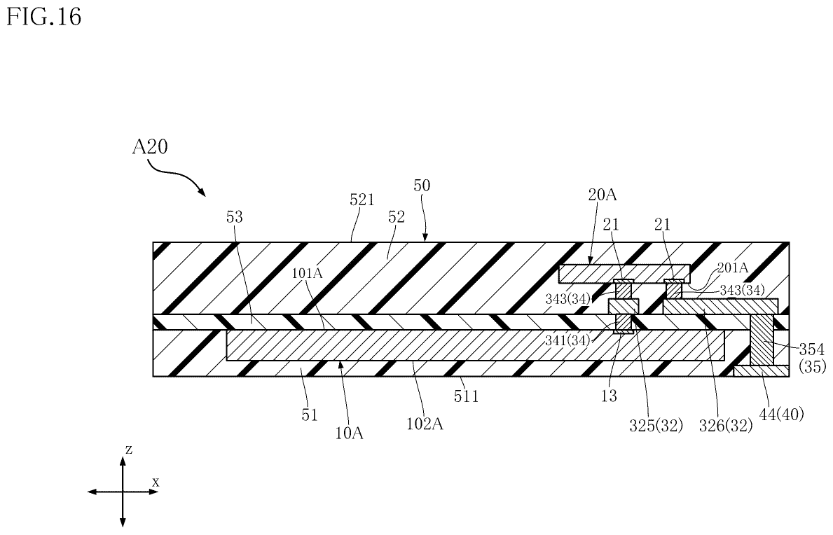

FIGS. 12 to 16 show a semiconductor device A20 according to a second embodiment of the present disclosure. FIG. 12 is a plan view of the semiconductor device A20, showing the sealing part 50 as transparent. In FIG. 12, the outline of the sealing part 50 is indicated with an imaginary line (dash-double dot line). FIG. 13 is a sectional view taken along line XIII-XIII in FIG. 12. FIG. 14 is a sectional view taken along line XIV-XIV in FIG. 12. FIG. 15 is a sectional view taken along line XV-XV in FIG. 12. FIG. 16 is a sectional view taken along line XVI-XVI in FIG. 12.

The semiconductor device A20 includes a switching element 10C, a switching element 10D, a control element 20A, a wiring layer 32, a plurality of interconnect wirings 34, a plurality of communication wirings 35, a plurality of terminals 40, and a sealing part 50. The semiconductor device A20 of the present embodiment differs from the semiconductor device A10 in the following respects: the plan-view shape and layout of the switching elements 10C and 10D and the control element 20A; the arrangement of the electrodes 11 to 16 of the switching elements 10C and 10D; the arrangement of the plurality of pads 21 of the control element 20A; the electrical connections of the electrodes of the switching elements 10C an 10D with the wiring layer 32; and the arrangements of the interconnect wirings 34, the communication wirings 35, and the terminals 40.

The switching elements 10C and 10D of the semiconductor device A20 are HEMTs that are made of a material, including gallium nitride (GaN). As shown in FIGS. 12 to 16, the switching element 10C has a first obverse surface 101C, a first reverse surface 102C, a first electrode 11, a second electrode 12, and a third electrode 13. The first obverse surface 101C is oriented toward the z1 side in the thickness direction z, and the first, second, and third electrodes 11, 12, and 13 are formed on the first obverse surface 101C.

As can be understood from FIGS. 12 to 14, the first electrode 11 and the second electrode 12 each extend in the first direction x. The first electrode 11 and the second electrode 12 are located along the opposite edges of the switching element 10C in the second direction y. The first electrode 11 corresponds to the source of the switching element 10C, and the second electrode 12 to the drain of the switching element 10C.

As shown in FIGS. 12, 14, and 16, the third electrode 13 is located near the edge of the switching element 10C in the first direction x and also near the edge in the second direction y. The third electrode 13 corresponds to the gate of the switching element 10C. The switching element 10C is not limited to this example in terms of the shape, number, and arrangement of the first, second, and third electrodes 11, 12, and 13, and various modifications are possible. The switching element 10C of the configuration described above is an example of the “first semiconductor element” of the present disclosure.

As shown in FIGS. 13 to 15, the switching element 10D is located on the z1 side in the thickness direction z with respect to the switching element 10C. The switching element 10D overlaps with the switching element 10C as viewed in the thickness direction z. As shown in FIGS. 12 to 15, the switching element 10D has a second obverse surface 11D, a second reverse surface 102D, a plurality of (two) fourth electrodes 14, a fifth electrode 15, and a sixth electrode 16. The second obverse surface 101D is oriented toward the z2 side in the thickness direction z, and the fourth, fifth, and sixth electrodes 14, 15, and 16 are formed on the second obverse surface 1D.

As shown in FIGS. 12 and 15, the plurality of (two) fourth electrodes 14 and the fifth electrode 15 each extend in the first direction x. The two fourth electrodes 14 are disposed on opposite sides of the switching element 10D in the second direction y. The fifth electrode 15 is located between the two fourth electrodes 14 in the second direction y. As can be understood from FIGS. 12 to 14, the fifth electrode 15 overlaps with the first electrode 11 of the switching element 10C as viewed in the thickness direction z. The fourth electrodes 14 each correspond to the source of the switching element 10D, and the fifth electrode 15 to the drain of the switching element 10D.

As shown in FIGS. 12, 14, and 15, the sixth electrode 16 is located near the edge of the switching element 10D in the first direction x and also near the edge the second direction y. The sixth electrode 16 corresponds to the gate of the switching element 10D. As shown in FIGS. 13 and 14 in particular, the switching element 10D is electrically connected to the switching element 10C via the wiring layer 32. The switching element 10D is not limited to this example in terms of the shape, number, and arrangement of the fourth, fifth, and sixth electrodes 14, 15, and 16, and various modifications are possible. The switching element 10D of the configuration described above is an example of the “second semiconductor element” of the present disclosure.

The semiconductor device A20 is formed as a half-bridge switching circuit, for example. In this case, the switching element 10C forms the upper arm circuit of the semiconductor device A20, and the switching element 10D forms the lower arm circuit. The switching elements 10C and 10D are connected in series.

As shown in FIGS. 14 and 16, the control element 20A is located on the z1 side in the thickness direction z with respect to the switching element 10C. The control element 20A overlaps with the switching element 10C as viewed in the thickness direction z. As shown in FIG. 12, the control element 20A has a smaller area than each of the switching elements 10C and 10D as viewed in the thickness direction z.

The control element 20A is electrically connected to the switching elements 10C and 10D. The control element 20A is a gate driver that applies gate voltage to the third electrode 13 of the switching element 10C and the sixth electrode 16 of the switching element 10D.

As shown in FIGS. 12, 14, and 16, the control element 20A has a third obverse surface 201A and a plurality of (four) pads 21. The third obverse surface 201A is oriented toward the z2 side in the thickness direction z. The third obverse surface 201A faces the first obverse surface 101C of the switching element 10C. The plurality of pads 21 are formed on the third obverse surface 201A. As shown in FIGS. 12, 14, and 16, each pad 21 is rectangular as viewed in the thickness direction. The control element 20A is not limited to this example in terms of the shape, number, and arrangement of the pads 21, and various modifications are possible. The control element 20A of the configuration described above is an example of the “third semiconductor element” of the present disclosure.

As shown in FIGS. 13 to 16, the wiring layer 32 is located between the switching element 10C and each of the switching element 10D and the control element 20A in the thickness direction z. That is, the wiring layer 32 is located on the z1 side in the thickness direction z with respect to the switching element 10C. The switching element 10D and the control element 20A are located on the z1 side in the thickness direction z with respect to the wiring layer 32. The wiring layer 32 is located between the third sealing part 53 and the second sealing part 52. At least a portion of the wiring layer 32 is embedded in the second sealing part 52. The constituent material of the wiring layer 32 is not specifically limited and may include copper (Cu), for example.

As shown in FIGS. 12 to 16, the wiring layer 32 includes a sixth wiring 321, a seventh wiring 322, an eighth wiring 323, a ninth wiring 324, a tenth wiring 325, and a control wiring 326. In the illustrated example, two sixth wirings 321 are disposed at two separate locations. The two sixth wirings 321 are located at the positions corresponding to the plurality of (two) fourth electrodes 14 of the switching element 10D. Each sixth wiring 321 overlaps with the corresponding fourth electrode 14 as viewed in the thickness direction z. As shown in FIGS. 13 to 15, each fourth electrode 14 of the switching element 10D is electrically connected to the sixth wiring 321 via one of the interconnect wirings 34.

As shown in FIGS. 12 to 14, the seventh wiring 322 overlaps with the first electrode 11 and the fifth electrode 15 as viewed in the thickness direction z. As shown in FIGS. 13 and 14, the first electrode 11 of the switching element 10C is electrically connected to the seventh wiring 322 via one of the interconnect wirings 34. Additionally, the fifth electrode 15 of the switching element 10D is electrically connected to the seventh wiring 322 via one of the interconnect wirings 34. That is, the fifth electrode 15 of the switching element 10D is electrically connected to the first electrode 11 of the switching element 10C via the wiring layer 32 (the seventh wiring 322).

The eighth wiring 323 is located at the position corresponding to the second electrode 12 of the switching element 10C. The eighth wiring 323 overlaps with the second electrode 12 as viewed in the thickness direction z. As shown in FIGS. 13 and 14, the second electrode 12 is electrically connected to the eighth wiring 323 via one of the interconnect wirings 34.

The ninth wiring 324 is located at the position corresponding to the third electrode 13 of the switching element 10C and one of the pads 21 of the control element 20A. The ninth wiring 324 overlaps with the third electrode 13 and the pad 21 as viewed in the thickness direction z. As shown in FIGS. 14 and 16, the third electrode 13 is electrically connected to the ninth wiring 324 via one of the interconnect wirings 34. Also, the pad 21 is electrically connected to the ninth wiring 324 via one of the interconnect wiring 34. Thus, the control element 20A (the relevant pad 21) is electrically connected to the third electrode 13 via the ninth wiring 324. The pad 21 that is electrically connected to the third electrode 13 via the ninth wiring 324 overlaps with the third electrode 13 as viewed in the thickness direction z.

The tenth wiring 325 is located at the position corresponding to the sixth electrode 16 of the switching element 10D and one of the pads 21 of the control element 20A. The tenth wiring 325 overlaps with the sixth electrode 16 and the pad 21 as viewed in the thickness direction z. As shown in FIG. 14, the sixth electrode 16 is electrically connected to the tenth wiring 325 via one of the interconnect wirings 34. Also, the pad 21 is electrically connected to the tenth wiring 325 via one of the interconnect wirings 34. Thus, the control element 20A (the relevant pad 21) is electrically connected to the sixth electrode 16 via the tenth wiring 325.

The control wiring 326 is located at the position corresponding to one of the pads 21 of the control element 20A. In the illustrated example, two control wirings 326 are disposed at two separate locations. The two control wirings 326 are located at the positions corresponding to two pads 21 of the control element 20A. Each control wiring 326 overlaps with the relevant pad 21 as viewed in the thickness direction z. As shown in FIGS. 12 and 16, each of the two pads 21 is electrically connected to one of the control wirings 326 via one of the interconnect wirings 34.

As shown in FIGS. 13 to 16, each interconnect wiring 34 is embedded in either the second sealing part 52 or the third sealing part 53. As shown in FIGS. 12 to 16, each interconnect wiring 34 overlaps with either the switching element 10C or 10D, or the control element 20A as viewed in the thickness direction z. Each interconnect wiring 34 is connected to the wiring layer 32 (one of the sixth, seventh, eighth, ninth, and tenth wirings 321, 322, 323, 324, and 325, or one of the control wirings 326).

As shown in FIGS. 12 to 16, the plurality of interconnect wirings 34 include a plurality of first interconnect wirings 341, a plurality of second interconnect wirings 342, and a plurality of third interconnect wirings 343.

As shown in FIGS. 13, 14, and 16, the plurality of first interconnect wirings 341 are interposed between the switching element 10C and the wiring layer 32 in the thickness direction z. In the illustrated example, the first interconnect wirings 341 are embedded in the third sealing part 53. Each first interconnect wiring 341 is connected to one of the first electrode 11, the second electrode 12, and the third electrode 13 of the switching element 10C. The constituent material of the first interconnect wirings 341 is the same as that of the wiring layer 32, and examples include copper (Cu).

As shown in FIGS. 13 to 15, the second interconnect wirings 342 are interposed between the switching element 10D and the wiring layer 32 in the thickness direction z. In the illustrated example, the second interconnect wirings 342 are embedded in the second sealing part 52. Each second interconnect wiring 342 is connected to one of the plurality of (two) fourth electrodes 14, the fifth electrode 15, and the sixth electrode 16 of the switching element 10D. The constituent material of the second interconnect wirings 342 is not specifically limited. In one example, the second interconnect wirings 342 are made of a conductive bonding material, such as solder.

As shown in FIGS. 14 and 16, the third interconnect wirings 343 are interposed between the control element 20A and the wiring layer 32 in the thickness direction z. In the illustrated example, the third interconnect wirings 343 are embedded in the second sealing part 52. Each third interconnect wiring 343 is connected to one of the plurality of (four) pads 21 of the control element 20A. The constituent material of the third interconnect wirings 343 is not specifically limited. In one example, the third interconnect wirings 343 are made of a conductive bonding material, such as solder.

As shown in FIGS. 13 to 16, the communication wirings 35 are embedded in the first sealing part 51 and the third sealing part 53. As shown in FIGS. 12 to 16, each communication wiring 35 overlaps with the wiring layer 32 (one of the sixth, seventh, and eighth wirings 321, 322 and 323, or one of the control wirings 326) as viewed in the thickness direction z. As shown in FIGS. 13 to 16, each communication wiring 35 is connected to the wiring layer 32 (one of the sixth, seventh, and eighth wirings 321, 322 and 323, or one of the control wirings 326). The constituent material of the communication wirings 35 is the same as that of the wiring layer 32, and examples include copper (Cu).

As shown in FIGS. 12 to 16, the plurality of communication wirings 35 include a plurality of first communication wirings 351, a plurality of second communication wirings 352, a plurality of third communication wirings 353, and a plurality of fourth communication wirings 354.

As shown in FIGS. 12 to 15, the plurality of first communication wirings 351 are connected to the sixth wiring 321 and a plurality of first terminals 41, which will be described later. As shown in FIGS. 12 and 15, the plurality of second communication wirings 352 are connected to the seventh wiring 322 and a second terminal 42, which will be described later. As shown in FIGS. 12 to 14, the plurality of third communication wirings 353 are connected to the eighth wiring 323 and a third terminal 43, which will be described later. As shown in FIGS. 12 and 16, each fourth communication wiring 354 is connected to one of the plurality of (two) control wirings 326 and one of a plurality of control terminals 44, which will be described later.

As shown in FIGS. 13 to 16, a portion of each terminal 40 is embedded in the first sealing part 51. The terminals 40 are located on the z1 side in the thickness direction z with respect to the first obverse surface 101C of the switching element 10C. The terminals 40 are exposed at the bottom surface 511 of the first sealing part 51. Each terminal 40 is connected to one of the communication wirings 35 (the first, second, third, and fourth communication wirings 351, 352, 353, and 354). Thus, each terminal 40 is electrically connected to either the switching element 10C or 10D, or the control element 20A via the wiring layer 32 (one of the sixth, seventh, eighth wirings 321, 322, and 323, or one of the control wiring 326). The constituent material of the terminals 40 is the same as that of the wiring layer 32, and examples include copper (Cu).

As shown in FIGS. 12 to 16, the plurality of terminals 40 include a plurality of (two) first terminals 41, a second terminal 42, a third terminal 43, and a plurality of (two) control terminals 44.

As shown in FIGS. 12 to 15, each of the two first terminals 41 are electrically connected to the sixth wiring 321 via a plurality of first communication wirings 351. As shown in FIGS. 12 to 14, the third terminal 43 is electrically connected to the eighth wiring 323 via a plurality of third communication wirings 353. The two first terminals 41 and the third terminal 43 are used to input direct current power that is to be converted by the switching elements 10D and 10C. The two first terminals 41 are negative terminals (N terminals). The third terminal 43 is a positive terminal (P terminal).

As shown in FIGS. 12 and 15, the second terminal 42 is electrically connected to the seventh wiring 322 via a plurality of second communication wirings 352. The second terminal 42 outputs the alternating current power resulting from the conversion by the switching elements 10C and 10D.

The plurality of (two) control terminals 44 are each electrically connected to one of the control wirings 326 via one of the fourth communication wirings 354. Hence, each control terminal 44 is electrically connected to the control element 20A. One of the control terminals 44 receives the power for driving the control element 20A. One of the control terminals 44 receives an electrical signal directed to the control element 20A.

The following describes the operation of the present embodiment.

The semiconductor device A20 includes: the switching element 10C (the first semiconductor element); the wiring layer 32 located on the z1 side in the thickness direction z with respect to the switching element 10C; and the switching element 10D (the second semiconductor element) located on the z1 side in the thickness direction z with respect to the wiring layer 32.

The switching element 10C has the first obverse surface 101C oriented toward the z1 side in the thickness direction z, and includes the first electrode 11, the second electrode 12, and the third electrode 13 formed on the first obverse surface 101C. The switching element 10C may be a lateral HEMT, for example. The switching element 10D is electrically connected to the switching element 10C via the wiring layer 32 and overlaps with the switching element 10C as viewed in the thickness direction z. In this configuration, a plurality of elements, including the lateral switching element 10C, are stacked in the thickness direction z. This allows for a reduction in the plan-view size (the size as viewed in the thickness direction z) of the semiconductor device A20, enabling the overall size reduction of the semiconductor device A20.

With the configuration described above, the conduction path between the elements (the switching elements 10C and 10D) can be shorter than in a configuration where the elements are arranged on the same plane. This helps to reduce the parasitic inductance caused by the internal interconnects of the semiconductor device A20.

The switching element 10D has the second obverse surface 101D and the fourth, fifth, and sixth electrodes 14, 15, and 16 formed on the second obverse surface 101D. The switching element 10D may be a lateral HEMT. The second obverse surface 101D is oriented toward the z2 side in the thickness direction z, facing the first obverse surface 101C of the switching element 10C. With this configuration, the conduction path is appropriately shorter between an electrode of the switching element 10C (the first electrode 11) and an electrode of the switching element 10D (the fifth electrode 15) that are electrically connected via the wiring layer 32 (the seventh wiring 322). This is desirable for reducing the internal parasitic inductance of the semiconductor device A20.

The wiring layer 32 includes the sixth wiring 321, the seventh wiring 322, and the eighth wiring 323. As shown in FIGS. 13 and 14, for the semiconductor device A20, the first electrode 11 (the source) of the switching element 10C (the upper arm) and the fifth electrode 15 (the drain) of the switching element 10D (the lower arm) are electrically connected to the seventh wiring 322. The fifth electrode 15 overlaps with the first electrode 11 as viewed in the thickness direction z. This configuration allows the first electrode 11 of the switching element 10C and the fifth electrode 15 of the switching element 10D to be connected by a conduction path that is substantially linear along the thickness direction z. This configuration is thus suitable for shortening the conduction path between the first electrode 11 and the fifth electrode 15, thus reducing the internal parasitic inductance of the semiconductor device A20.

The semiconductor device A20 includes the control element 20A (the third semiconductor element) located on the z1 side in the thickness direction z with respect to the wiring layer 32.

The control element 20A overlaps with the switching element 10C (the first semiconductor element) as viewed in the thickness direction z. With this configuration, the semiconductor device A20 provided with the plurality of elements (including the lateral switching elements 10C and 10D, and the control element 20A) can be more compact in plan-view size (the size as viewed in the thickness direction z). Thus, the overall size of the semiconductor device A20 can be reduced.

The wiring layer 32 includes the ninth wiring 324 and the tenth wiring 325. The control element 20A has the third obverse surface 201A oriented toward the z2 side in the thickness direction z and the plurality of pads 21 formed on the third obverse surface 201A. One of the pads 21 is electrically connected to the third electrode 13 (the gate) of the switching element 10C via the ninth wiring 324. One of the pads 21 is electrically connected to a sixth electrode 16 (the gate) of the switching element 10D via the tenth wiring 325. This ensures that the conduction path is appropriately shorter between the third electrode 13 of the switching element 10C or the sixth electrode 16 of the switching element 10D and the relevant pad 21 that are electrically connected via the wiring layer 32 (the ninth wiring 324 and the tenth wiring 325). This is desirable for reducing the internal parasitic inductance of the semiconductor device A20.

Among the plurality of pads 21 of the control element 20A, one that is electrically connected to the third electrode 13 via the ninth wiring 324 overlaps with the third electrode 13 as viewed in the thickness direction z. This configuration allows the third electrode 13 of the switching element 10C and the pad 21 of the control element 20A to be connected by a conduction path that is substantially linear along the thickness direction z. This configuration is thus suitable for shortening the conduction path between the third electrode 13 and the pad 21, and thus reducing the internal parasitic inductance of the semiconductor device A20.

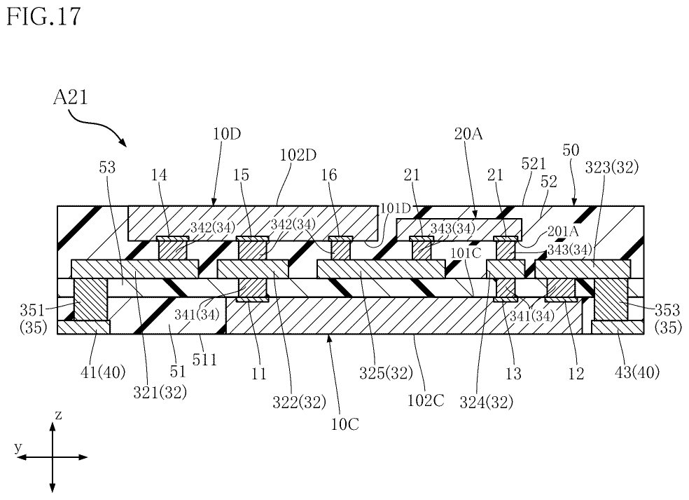

FIG. 17 shows a semiconductor device according to a first variation of the second embodiment. FIG. 17 is a sectional view of a semiconductor device A21 according to this variation, showing a section taken along the same line as FIG. 14 of the second embodiment.

For the semiconductor device A21 of this variation, the switching elements 10C and 10D respectively have a first reverse surface 102C and a second reverse surface 102D that are exposed from the sealing part 50. More specifically, the first reverse surface 102C of the switching element 10C is exposed from the first sealing part 51. In the illustrated example, the first reverse surface 102C of the switching element 10C is flush with the bottom surface 511 of the first sealing part 51. The second reverse surface 102D of the switching element 10D is exposed from the second sealing part 52. In the illustrated example, the second reverse surface 102D of the switching element 10D is flush with the top surface 521 of the second sealing part 52.

For the semiconductor device A21, the first reverse surface 102C of the switching element 10C is exposed from the first sealing part 51, and the second reverse surface 102D of the switching element 10D from the second sealing part 52. This configuration ensures that heat generated by the switching elements 10C and 10D is efficiently dissipated to the outside of the semiconductor device A21. Thus, the heat dissipation of the semiconductor device A21 is improved.

In the semiconductor device A21, the first reverse surface 102C is exposed from the first sealing part 51 (the sealing part 50) and thus can be bonded to a circuit board, for example. In addition, the second reverse surface 102D is exposed from the second sealing part 52 (the sealing part 50) and thus can be bonded to a heat dissipating member, for example. This helps to further improve the heat dissipation of the semiconductor device A21. In an example different from FIG. 17, the control element 20A may be configured such that its surface oriented toward the z1 side in the thickness direction z is exposed from the second sealing part 52 (the sealing part 50). This example ensure that heat generated by the control element 20A is efficiently dissipated to the outside of the semiconductor device A21. The semiconductor device A21 additionally achieves the same operation and effects as those achieved by the semiconductor device A20.

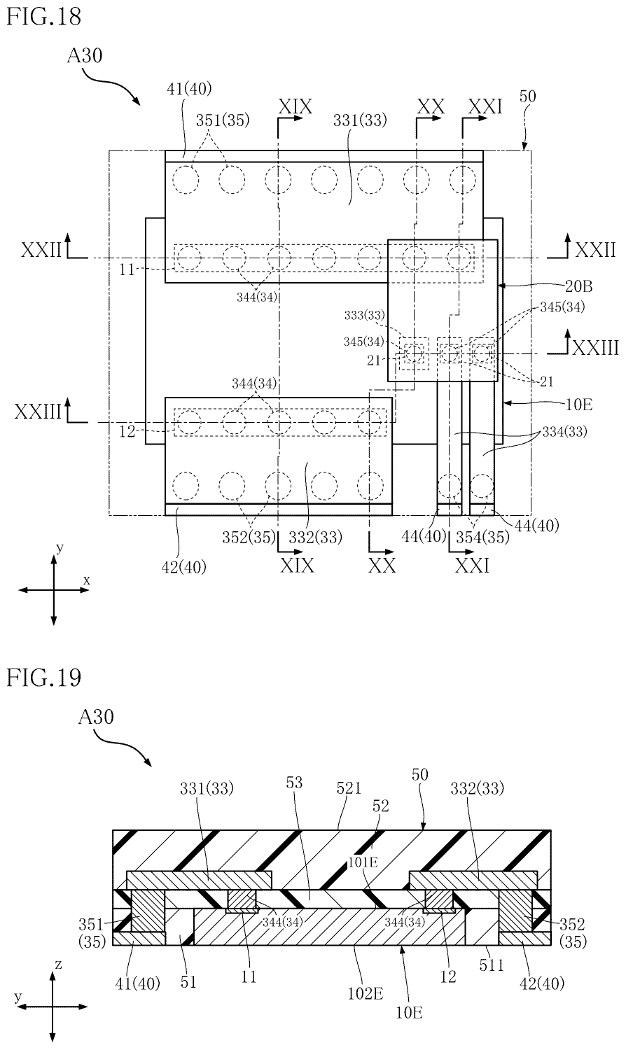

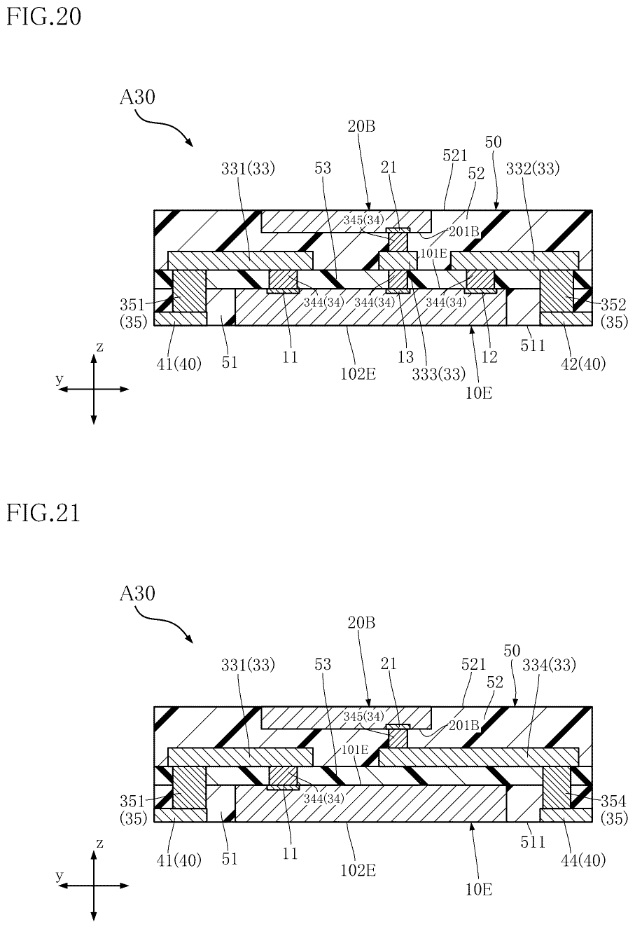

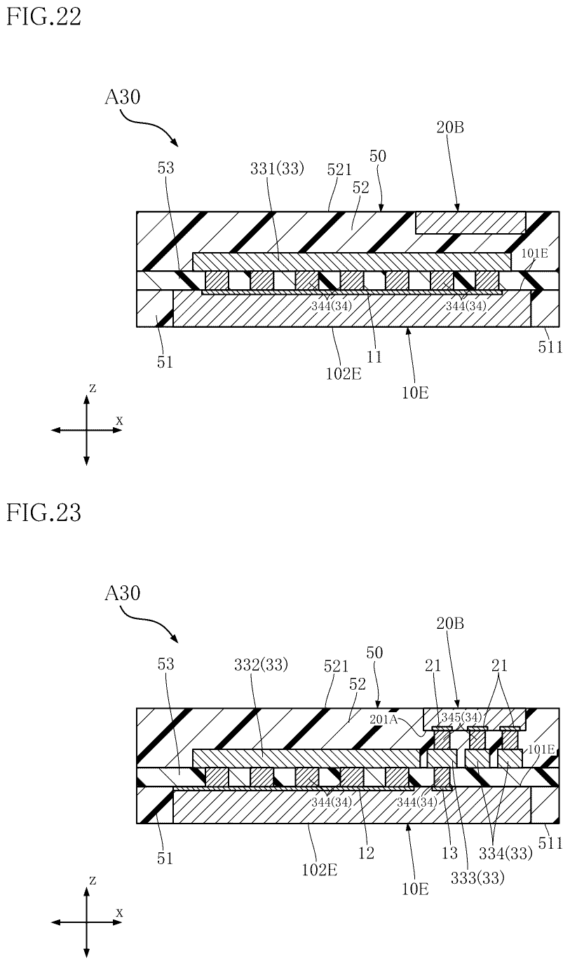

FIGS. 18 to 23 show a semiconductor device A30 according to a third embodiment of the present disclosure. FIG. 18 is a plan view of the semiconductor device A30, showing the sealing part 50 as transparent. In FIG. 18, the outline of the sealing part 50 is indicated with an imaginary line (dash-double dot line). FIG. 19 is a sectional view taken along line XIX-XIX in FIG. 18. FIG. 20 is a sectional view taken along line XX-XX in FIG. 18. FIG. 21 is a sectional view taken along line XXI-XXI in FIG. 18. FIG. 22 is a sectional view taken along line XXII-XXII in FIG. 18. FIG. 23 is a sectional view taken along line XXIII-XXIII in FIG. 18.

The semiconductor device A30 includes a switching element 10E, a control element 20B, a wiring layer 33, a plurality of interconnect wirings 34, a plurality of communication wirings 35, a plurality of terminals 40, and a sealing part 50.

The switching element 10E of the semiconductor device A30 is a HEMT that is made of a material, including gallium nitride (GaN). As shown in FIGS. 18 to 23, the switching element 10E has a first obverse surface 101E, a first reverse surface 102E, a first electrode 11, a second electrode 12, and a third electrode 13. The first obverse surface 101E is oriented toward the z1 side in the thickness direction z, and the first, second, and third electrodes 11, 12, and 13 are formed on the first obverse surface 101E.

As shown in FIGS. 18, 22, and 23, the first electrode 11 and the second electrode 12 each extend in the first direction x. The first electrode 11 and the second electrode 12 are located along the opposite edges of the switching element 10E in the second direction y. The electric current corresponding to the power to be converted by the switching element 10E flows through the second electrode 12. Thus, the second electrode 12 corresponds to the drain of the switching element 10E. The electric current corresponding to the power converted by the switching element 10E flows through the first electrode 11. Thus, the first electrode 11 corresponds to the source of the switching element 10E.

As can be understood from FIGS. 18, 20, and 23, the third electrode 13 is located near the edge of the switching element 10E in the first direction x and the second direction y. The third electrode 13 receives a gate voltage that controls the drive of the switching element 10E. The third electrode 13 corresponds to the gate of the switching element 10E. The switching element 10E is not limited to this example in terms of the shape, number, and arrangement of the first, second, and third electrodes 11, 12, and 13, and various modifications are possible. The switching element 10E of the configuration described above is an example of the “first semiconductor element” of the present disclosure.

For the semiconductor device A30, the first reverse surface 102E of the switching element 10E is exposed from the sealing part 50. More specifically, the first reverse surface 102E of the switching element 10E is exposed from the first sealing part 51. In the illustrated example, the first reverse surface 102E of the switching element 10E is flush with the bottom surface 511 of the first sealing part 51.

As shown in FIGS. 20 to 23, the control element 20B is located on the z1 side in the thickness direction z with respect to the switching element 10E. The control element 20B overlaps with the switching element 10E as viewed in the thickness direction z. As shown in FIG. 18, the control element 20B has a smaller area than the switching element 10E as viewed in the thickness direction Z.

The control element 20B is electrically connected to the switching element 10E via the wiring layer 33. The control element 20B is a gate driver that applies gate voltage to the third electrode 13 of the switching element 10E.

As shown in FIGS. 18, 20, 21, and 23, the control element 20B has an element obverse surface 201B and a plurality of (three) pads 21. The element obverse surface 201B is oriented toward the z2 side in the thickness direction z. The element obverse surface 201B faces the first obverse surface 101E of the switching element 10E. The plurality of pads 21 are formed on the element obverse surface 201B. As shown in FIG. 18, each pad 21 is rectangular as viewed in the thickness direction. The control element 20B is not limited to this example in terms of the shape, number, and arrangement of the pads 21, and various modifications are possible. The control element 20B of the configuration described above is an example of the “second semiconductor element” of the present disclosure.

For the semiconductor device A30, the control element 20B has a surface that is oriented toward the z1 side in the thickness direction z (the surface facing away from the element obverse surface 201B) and exposed from the sealing part 50. More specifically, the surface of the control element 20B oriented toward the z1 side in the thickness direction z is exposed from the second sealing part 52. In the illustrated example, the surface of the control element 20B oriented toward the z1 side in the thickness direction z is flush with the top surface 521 of the second sealing part 52.

As shown in FIGS. 19 to 23, the wiring layer 33 is located between the switching element 10E and the control element 20B in the thickness direction z. That is, the wiring layer 33 is located on the z1 side in the thickness direction z with respect to the switching element 10E. The control element 20B is located on the z1 side in the thickness direction z with respect to the wiring layer 33. The wiring layer 33 is located between the third sealing part 53 and the second sealing part 52. At least a portion of the wiring layer 33 is embedded in the second sealing part 52. The constituent material of the wiring layer 33 is not specifically limited and may include copper (Cu), for example.

As shown in FIGS. 18 to 23, the wiring layer 33 includes an eleventh wiring 331, a twelfth wiring 332, a thirteenth wiring 333, and a control wiring 334. As shown in FIGS. 18 to 22, the eleventh wiring 331 is located at the position corresponding to the first electrode 11 of the switching element 10E. The eleventh wiring 331 overlaps with the first electrode 11 as viewed in the thickness direction z. As shown in FIGS. 19 to 22, the first electrode 11 of the switching element 10E is electrically connected to the eleventh wiring 331 via one of the interconnect wirings 34.

As shown in FIGS. 18 to 20 and 23, the twelfth wiring 332 is located at the position corresponding to the second electrode 12 of the switching element 10E. The twelfth wiring 332 overlaps with the second electrode 12 as viewed in the thickness direction z. As shown in FIGS. 19, 20 and 23, the second electrode 12 of the switching element 10E is electrically connected to the twelfth wiring 332 via one of the interconnect wirings 34.

As shown in FIGS. 18, 20, and 23, the thirteenth wiring 333 is located at the position corresponding to the third electrode 13 of the switching element 10E and one of the pads 21 of the control element 20B. The thirteenth wiring 333 overlaps with the third electrode 13 and the pad 21 as viewed in the thickness direction z. As shown in FIGS. 20 and 23, the third electrode 13 is electrically connected to the thirteenth wiring 333 via one of the interconnect wirings 34. Also, the pad 21 is electrically connected to the thirteenth wiring 333 via one of the interconnect wirings 34. Thus, the control element 20B (the relevant pad 21) is electrically connected to the third electrode 13 via the thirteenth wiring 333. The pad 21 that is electrically connected to the third electrode 13 via the thirteenth wiring 333 (the wiring layer 33) overlaps with the third electrode 13 as viewed in the thickness direction z.

The control wiring 334 is located at the position corresponding to one of the pads 21 of the control element 20B. In the illustrated example, two control wirings 334 are disposed at two separate locations. The two control wirings 334 are located at the positions corresponding to two pads 21 of the control element 20B. Each control wiring 334 overlaps with the relevant pad 21 as viewed in the thickness direction z. As shown in FIGS. 18 and 21, each of the two pads 21 is electrically connected to the control wiring 334 via one of the interconnect wirings 34.

As shown in FIGS. 19 to 23, each interconnect wiring 34 is embedded in either the second sealing part 52 or the third sealing part 53. As shown in FIGS. 18 to 23, each interconnect wiring 34 overlaps with either the switching element 10E or the control element 20B as viewed in the thickness direction z. Each interconnect wiring 34 is connected to the wiring layer 33 (either the eleventh, twelfth, or thirteenth wiring 331, 332, or 333, or the control wiring 334).

As shown in FIGS. 19 to 23, the plurality of interconnect wirings 34 include a plurality of fourth interconnect wirings 344, and a plurality of fifth interconnect wirings 345.

As shown in FIGS. 19 to 23, the fourth interconnect wirings 344 are interposed between the switching element 10E and the wiring layer 33 in the thickness direction z. In the illustrated example, the fourth interconnect wirings 344 are embedded in the third sealing part 53. Each fourth interconnect wiring 344 is connected to one of the first, second, and third electrodes 11, 12, and 13 of the switching element 10E. The constituent material of the fourth interconnect wirings 344 is the same as that of the wiring layer 33, and examples include copper (Cu).

As shown in FIGS. 20, 21, and 23, the plurality of fifth interconnect wirings 345 are interposed between the control element 20B and the wiring layer 33 in the thickness direction z. In the illustrated example, the fifth interconnect wirings 345 are embedded in the second sealing part 52. Each fifth interconnect wiring 345 is connected to one of the plurality of (three) pads 21 of the control element 20B. The constituent material of the fifth interconnect wirings 345 is not specifically limited. In one example, the fifth interconnect wirings 345 are made of a conductive bonding material, such as solder.

As shown in FIGS. 19 to 21, the communication wirings 35 are each embedded in both the second sealing part 52 and the third sealing part 53. As shown in FIGS. 18 to 21, each communication wiring 35 overlaps with the wiring layer 33 (either the eleventh or twelfth wiring 331 or 332, or the control wiring 334) as viewed in the thickness direction z. As shown in FIGS. 19 to 21, each communication wiring 35 is connected to the wiring layer 33 (either the eleventh or twelfth wiring 331 or 332, or the control wiring 334). The constituent material of the communication wirings 35 is the same as that of the wiring layer 33, and examples include copper (Cu).

As shown in FIGS. 18 to 21, the plurality of communication wirings 35 include a plurality of first communication wirings 351, a plurality of second communication wirings 352, and a plurality of fourth communication wirings 354.

As shown in FIGS. 18 to 21, the plurality of first communication wirings 351 are connected to the eleventh wiring 331 and a first terminal 41, which will be described later. As shown in FIGS. 18 to 20, the plurality of second communication wiring 352 are connected to the twelfth wiring 332 and a second terminal 42, which will be described later. As shown in FIGS. 18 and 21, each fourth communication wiring 354 is connected to one of the plurality of (two) control wirings 334 and one of a plurality of control terminals 44, which will be described later.

As shown in FIGS. 19 to 21, a portion of each terminal 40 is embedded in the first sealing part 51. The terminals 40 are exposed at the bottom surface 511 of the first sealing part 51. Each terminal 40 is connected to one of the communication wirings 35 (the first, second, and fourth communication wirings 351, 352, and 354). Thus, each terminal 40 is electrically connected to at least one of the switching element 10E or the control element 20B via the wiring layer 33 (one of the eleventh and twelfth wirings 331 and 332 or one of the control wirings 334). The constituent material of the terminals 40 is the same as that of the wiring layer 33, and examples include copper (Cu).

As shown in FIGS. 18 to 21, the plurality of terminals 40 include a first terminal 41, a second terminal 42, and a plurality of (two) control terminals 44.

As shown in FIGS. 18 to 21, the first terminal 41 is electrically connected to the eleventh wiring 331 via the first communication wirings 351. The first electrode 11 of the switching element 10E is electrically connected to the eleventh wiring 331 via the fourth interconnect wirings 344. Thus, the first terminal 41 is electrically connected to the first electrode 11 via the eleventh wiring 331. With the first electrode 11 being the source, the first terminal 41 is a source terminal.

As shown in FIGS. 18 to 20, the second terminal 42 is electrically connected to the twelfth wiring 332 via the second communication wirings 352. The second electrode 12 of the switching element 10E is electrically connected to the twelfth wiring 332 via the fourth interconnect wirings 344. Thus, the second terminal 42 is electrically connected to the second electrode 12 via the twelfth wiring 332. With the second electrode 12 being the drain, the second terminal 42 is a drain terminal.

The plurality of (two) control terminals 44 are each electrically connected to one of the control wirings 326 via one of the fourth communication wirings 354. Hence, each control terminal 44 is electrically connected to the control element 20B. One of the control terminals 44 receives the power for driving the control element 20B. The other control terminals 44 receives an electrical signal directed to the control element 20B.

The following describes the operation of the present embodiment.

The semiconductor device A30 includes: the switching element 10E (the first semiconductor element); the wiring layer 33 located on the z1 side in the thickness direction z with respect to the switching element 10E; and the control element 20B (the second semiconductor element) located on the z1 side in the thickness direction z with respect to the wiring layer 33. The switching element 10E has the first obverse surface 101E oriented toward the z1 side in the thickness direction z, and includes the first electrode 11, the second electrode 12, and the third electrode 13 formed on the first obverse surface 101E. The switching element 10E may be a lateral HEMT, for example. The control element 20B is electrically connected to the switching element 10E via the wiring layer 33 and overlaps with the switching element 10E as viewed in the thickness direction z. In this configuration, a plurality of elements, including the lateral switching element 10E, are stacked in the thickness direction z. This allows for a reduction in the plan-view size (the size as viewed in the thickness direction z) of the semiconductor device A30, enabling the overall size reduction of the semiconductor device A30.

With the configuration described above, the conduction path between the elements (the switching element 10E and the control element 20B) can be shorter than in a configuration where the elements are arranged on the same plane. This helps to reduce the parasitic inductance caused by the internal interconnects of the semiconductor device A30.

The control element 20B has the element obverse surface 201B oriented toward the z2 side in the thickness direction z and the plurality of pads 21 formed on the element obverse surface 201B. One of the pads 21 is electrically connected to the third electrode 13 (the gate) of the switching element 10E via the wiring layer 33 (the thirteenth wiring 333). With this configuration, the conduction path is appropriately shorter between the third electrode 13 of the switching element 10E and the pad 21 of the control element 20B that is electrically connected to the third electrode 13 via the wiring layer 33 (the thirteenth wiring 333). This is desirable for reducing the internal parasitic inductance of the semiconductor device A30.

Among the plurality of pads 21 of the control element 20B, one that is electrically connected to the third electrode 13 via the thirteenth wiring 333 (the wiring layer 33) overlaps with the third electrode 13 as viewed in the thickness direction z. This configuration allows the third electrode 13 of the switching element 10E and the pad 21 of the control element 20B to be connected by a conduction path that is substantially linear in the thickness direction z. This configuration is thus suitable for shortening the conduction path between the third electrode 13 and the pad 21, and thus reducing the internal parasitic inductance of the semiconductor device A30.

For the semiconductor device A30, the first reverse surface 102E of the switching element 10E is exposed from the first sealing part 51, and the surface of the control element 20B that is oriented toward the z1 side in the thickness direction z is exposed from the second sealing part 52.

This configuration ensures that heat generated by the switching element 10E and the control element 20B is efficiently dissipated to the outside of the semiconductor device A30. Thus, the heat dissipation of the semiconductor device A30 is improved.

In the semiconductor device A30, the first reverse surface 102E is exposed from the first sealing part 51 (the sealing part 50) and thus can be bonded to a circuit board, for example. In addition, the surface of the control element 20B oriented toward the z1 side in the thickness direction z is exposed from the second sealing part 52 (the sealing part 50) and thus can be bonded to a heat dissipating member, for example. This engagement is effective in further improving the heat dissipation of the semiconductor device A30.

The semiconductor device according to the present disclosure is not limited to the embodiments described above. Various modifications in design may be made freely in the specific structure of each part of the semiconductor device according to the present disclosure.

The present disclosure covers the configurations of the following clauses.

### Clause 1.

A semiconductor device comprising:
a first semiconductor element including a first obverse surface oriented toward a first side in a thickness direction;
a wiring layer disposed on the first side in the thickness direction with respect to the first semiconductor element; and
a second semiconductor element disposed on the first side in the thickness direction with respect to the wiring layer,
wherein the first semiconductor element includes a first electrode, a second electrode, and a third electrode each formed on the first obverse surface,
the second semiconductor element overlaps with the first semiconductor element as viewed in the thickness direction, and
the second semiconductor element is electrically connected to the first semiconductor element via the wiring layer.

### Clause 2.

The semiconductor device according to Clause 1, wherein the second semiconductor element includes:
a second obverse surface oriented toward a second side in the thickness direction; and
a fourth electrode, a fifth electrode, and a sixth electrode each formed on the second obverse surface.

### Clause 3.

The semiconductor device according to Clause 2, wherein the wiring layer includes a first wiring, a second wiring, and a third wiring,
the first electrode is electrically connected to the first wiring,
the second electrode is electrically connected to the second wiring,
the fourth electrode is electrically connected to the second wiring, and
the fifth electrode is electrically connected to the third wiring.

### Clause 4.

The semiconductor device according to Clause 3, wherein the fourth electrode overlaps with the second electrode as viewed in the thickness direction.

### Clause 5.

The semiconductor device according to Clause 3 or 4, further comprising a third semiconductor element,
wherein the third semiconductor element is disposed on the first side in the thickness direction with respect to the wiring layer and is electrically connected to the wiring layer, and
the third semiconductor element overlaps with the first semiconductor element as viewed in the thickness direction.

### Clause 6.

The semiconductor device according to Clause 5, wherein the wiring layer includes a fourth wiring and a fifth wiring, and
the third semiconductor element is electrically connected to the third electrode via the fourth wiring and to the sixth electrode via the fifth wiring.

### Clause 7.

The semiconductor device according to Clause 6, wherein the first semiconductor element and the second semiconductor element are each a switching element,
the third semiconductor element is a control element,
the first electrode and the fourth electrode are each a source,
the second electrode and the fifth electrode are each a drain,
the third electrode and the sixth electrode are each a gate,
the third semiconductor element includes:
   a third obverse surface oriented toward the second side in the thickness direction; and
   a plurality of pads formed on the third obverse surface, and
the plurality of pads include a pad that is electrically connected to the fourth wiring and a pad that is electrically connected to the fifth wiring.

### Clause 8.

The semiconductor device according to Clause 2, wherein the wiring layer includes a sixth wiring, a seventh wiring, and an eighth wiring,
the first electrode is electrically connected to the seventh wiring,
the second electrode is electrically connected to the eighth wiring,
the fourth electrode is electrically connected to the sixth wiring, and
the fifth electrode is electrically connected to the seventh wiring.

### Clause 9.

The semiconductor device according to Clause 8, wherein the fifth electrode overlaps with the first electrode as viewed in the thickness direction.

### Clause 10.

The semiconductor device according to Clause 8 or 9, further comprising a third semiconductor element,
wherein the third semiconductor element is disposed on the first side in the thickness direction with respect to the wiring layer and is electrically connected to the wiring layer, and
the third semiconductor element overlaps with the first semiconductor element as viewed in the thickness direction.

### Clause 11.

The semiconductor device according to Clause 10, wherein the wiring layer includes a ninth wiring and a tenth wiring, and
the third semiconductor element is electrically connected to the third electrode via the ninth wiring and to the sixth electrode via the tenth wiring.

### Clause 12.

The semiconductor device according to Clause 11, wherein the first semiconductor element and the second semiconductor element are each a switching element,
the third semiconductor element is a control element,
the first electrode and the fourth electrode are each a source,
the second electrode and the fifth electrode are each a drain,
the third electrode and the sixth electrode are each a gate,
the third semiconductor element includes:
   a third obverse surface oriented toward the second side in the thickness direction; and
   a plurality of pads formed on the third obverse surface, and
the plurality of pads include a pad that is electrically connected to the ninth wiring and a pad that is electrically connected to the tenth wiring.

### Clause 13.

The semiconductor device according to Clause 12, wherein the pad that is electrically connected to the third electrode via the ninth wiring overlaps with the third electrode as viewed in the thickness direction.

### Clause 14.

The semiconductor device according to any one of Clauses 7, 12, and 13, further comprising a plurality of terminals disposed on the second side in the thickness direction with respect to the first obverse surface,
wherein the plurality of terminals are each electrically connected to one of the first semiconductor element, the second semiconductor element, and the third semiconductor element.

### Clause 15.

The semiconductor device according to any one of Clauses 7, 12, and 13, further comprising a plurality of interconnect wirings connected to the wiring layer,
wherein the plurality of interconnect wirings include a plurality of first interconnect wirings, a plurality of second interconnect wirings, and a plurality of third interconnect wirings,
the plurality of first interconnect wirings are interposed between the first semiconductor element and the wiring layer in the thickness direction and are each connected to one of the first electrode, the second electrode, and the third electrode,
the plurality of second interconnect wirings are interposed between the second semiconductor element and the wiring layer in the thickness direction and are each connected to one of the fourth electrode, the fifth electrode, and the sixth electrode, and
the plurality of third interconnect wirings are interposed between the third semiconductor element and the wiring layer in the thickness direction and are each connected to one of the plurality of pads.

### Clause 16.

The semiconductor device according to any one of Clauses 2 to 15, further comprising a sealing part covering at least a portion of each of the first semiconductor element and the second semiconductor element.

### Clause 17.

The semiconductor device according to Clause 16, wherein the sealing part includes a first sealing part and a second sealing part,
the first sealing part covers at least a portion of the first semiconductor element, and
the second sealing part is disposed on the first side in the thickness direction with respect to the first sealing part and covers at least a portion of the second semiconductor element.

### Clause 18.

The semiconductor device according to Clause 17, wherein the first semiconductor element includes a first reverse surface that is spaced apart from the first obverse surface in the thickness direction and is oriented toward the second side in the thickness direction,
the second semiconductor element includes a second reverse surface that is spaced apart from the second obverse surface in the thickness direction and is oriented toward the first side in the thickness direction, the first reverse surface is exposed from the first sealing part, and the second reverse surface is exposed from the second sealing part.

### Clause 19.

The semiconductor device according to Clause 1, wherein the first semiconductor element is a switching element,
the second semiconductor element is a control element,
the first electrode is a source,
the second electrode is a drain,
the third electrode is a gate, and
the second semiconductor element is electrically connected to the third electrode via the wiring layer.

### REFERENCE NUMERALS

A10, A11, A20, A21, A30: semiconductor device
10A, 10C, 10E: switching element (first semiconductor element)
10B, 10D: switching element (second semiconductor element)
101A, 101C, 101E: first obverse surface
10B, 10D: second obverse surface
102A, 102C, 102E: first reverse surface
102B, 102D: second reverse surface
11: first electrode (source) 12: second electrode (drain)
13: third electrode (gate) 14: fourth electrode (source)
15: fifth electrode (drain) 16: sixth electrode (gate)
20A: control element (third semiconductor element)
201A: third obverse surface
20B: control element (second semiconductor element)
201B: element obverse surface
21: pad 31, 32, 33: wiring layer
311: first wiring 312: second wiring
313: third wiring 314: fourth wiring
315: fifth wiring 316: control wiring
321: sixth wiring 322: seventh wiring
323: eighth wiring 324: ninth wiring
325: tenth wiring 326: control wiring
331: eleventh wiring 332: twelfth wiring
333: thirteenth wiring 334: control wiring
34: interconnect wiring 341: first interconnect wiring
342: second interconnect wiring 343: third interconnect wiring
344: fourth interconnect wiring 345: fifth interconnect wiring
35: communication wiring 351: first communication wiring
352: second communication wiring 353: third communication wiring
354: fourth communication wiring 40: terminal
41: first terminal 42: second terminal
43: third terminal 44: control terminal
50: sealing part 51: first sealing part
511: bottom surface 52: second sealing part
521: top surface 53: third sealing part

1. A semiconductor device comprising:
a first semiconductor element including a first obverse surface oriented toward a first side in a thickness direction;
a wiring layer disposed on the first side in the thickness direction with respect to the first semiconductor element; and
a second semiconductor element disposed on the first side in the thickness direction with respect to the wiring layer,
wherein the first semiconductor element includes a first electrode, a second electrode, and a third electrode each formed on the first obverse surface,
the second semiconductor element overlaps with the first semiconductor element as viewed in the thickness direction, and
the second semiconductor element is electrically connected to the first semiconductor element via the wiring layer.

2. The semiconductor device according to claim 1, wherein the second semiconductor element includes:
a second obverse surface oriented toward a second side in the thickness direction; and
a fourth electrode, a fifth electrode, and a sixth electrode each formed on the second obverse surface.

3. The semiconductor device according to claim 2, wherein the wiring layer includes a first wiring, a second wiring, and a third wiring,
the first electrode is electrically connected to the first wiring,
the second electrode is electrically connected to the second wiring,
the fourth electrode is electrically connected to the second wiring, and
the fifth electrode is electrically connected to the third wiring.

4. The semiconductor device according to claim 3, wherein the fourth electrode overlaps with the second electrode as viewed in the thickness direction.

5. The semiconductor device according to claim 3, further comprising a third semiconductor element,
wherein the third semiconductor element is disposed on the first side in the thickness direction with respect to the wiring layer and is electrically connected to the wiring layer, and
the third semiconductor element overlaps with the first semiconductor element as viewed in the thickness direction.

6. The semiconductor device according to claim 5, wherein the wiring layer includes a fourth wiring and a fifth wiring, and
the third semiconductor element is electrically connected to the third electrode via the fourth wiring and to the sixth electrode via the fifth wiring.

7. The semiconductor device according to claim 6, wherein the first semiconductor element and the second semiconductor element are each a switching element,
the third semiconductor element is a control element,
the first electrode and the fourth electrode are each a source,
the second electrode and the fifth electrode are each a drain,
the third electrode and the sixth electrode are each a gate,
the third semiconductor element includes:
a third obverse surface oriented toward the second side in the thickness direction; and
a plurality of pads formed on the third obverse surface, and
the plurality of pads include a pad that is electrically connected to the fourth wiring and a pad that is electrically connected to the fifth wiring.

8. The semiconductor device according to claim 2, wherein the wiring layer includes a sixth wiring, a seventh wiring, and an eighth wiring,
the first electrode is electrically connected to the seventh wiring,
the second electrode is electrically connected to the eighth wiring,
the fourth electrode is electrically connected to the sixth wiring, and
the fifth electrode is electrically connected to the seventh wiring.

9. The semiconductor device according to claim 8, wherein the fifth electrode overlaps with the first electrode as viewed in the thickness direction.

10. The semiconductor device according to claim 8, further comprising a third semiconductor element,
wherein the third semiconductor element is disposed on the first side in the thickness direction with respect to the wiring layer and is electrically connected to the wiring layer, and
the third semiconductor element overlaps with the first semiconductor element as viewed in the thickness direction.

11. The semiconductor device according to claim 10, wherein the wiring layer includes a ninth wiring and a tenth wiring, and
the third semiconductor element is electrically connected to the third electrode via the ninth wiring and to the sixth electrode via the tenth wiring.

12. The semiconductor device according to claim 11, wherein the first semiconductor element and the second semiconductor element are each a switching element,
the third semiconductor element is a control element,
the first electrode and the fourth electrode are each a source,
the second electrode and the fifth electrode are each a drain,
the third electrode and the sixth electrode are each a gate,
the third semiconductor element includes:
a third obverse surface oriented toward the second side in the thickness direction; and
a plurality of pads formed on the third obverse surface, and
the plurality of pads include a pad that is electrically connected to the ninth wiring and a pad that is electrically connected to the tenth wiring.

13. The semiconductor device according to claim 12, wherein the pad that is electrically connected to the third electrode via the ninth wiring overlaps with the third electrode as viewed in the thickness direction.

14. The semiconductor device according to claim 7, further comprising a plurality of terminals disposed on the second side in the thickness direction with respect to the first obverse surface,
wherein the plurality of terminals are each electrically connected to one of the first semiconductor element, the second semiconductor element, and the third semiconductor element.

15. The semiconductor device according to claim 7, further comprising a plurality of interconnect wirings connected to the wiring layer,
wherein the plurality of interconnect wirings include a plurality of first interconnect wirings, a plurality of second interconnect wirings, and a plurality of third interconnect wirings,
the plurality of first interconnect wirings are interposed between the first semiconductor element and the wiring layer in the thickness direction and are each connected to one of the first electrode, the second electrode, and the third electrode,
the plurality of second interconnect wirings are interposed between the second semiconductor element and the wiring layer in the thickness direction and are each connected to one of the fourth electrode, the fifth electrode, and the sixth electrode, and
the plurality of third interconnect wirings are interposed between the third semiconductor element and the wiring layer in the thickness direction and are each connected to one of the plurality of pads.

16. The semiconductor device according to claim 2, further comprising a sealing part covering at least a portion of each of the first semiconductor element and the second semiconductor element.

17. The semiconductor device according to claim 16, wherein the sealing part includes a first sealing part and a second sealing part,
the first sealing part covers at least a portion of the first semiconductor element, and
the second sealing part is disposed on the first side in the thickness direction with respect to the first sealing part and covers at least a portion of the second semiconductor element.

18. The semiconductor device according to claim 17, wherein the first semiconductor element includes a first reverse surface that is spaced apart from the first obverse surface in the thickness direction and is oriented toward the second side in the thickness direction,
the second semiconductor element includes a second reverse surface that is spaced apart from the second obverse surface in the thickness direction and is oriented toward the first side in the thickness direction,
the first reverse surface is exposed from the first sealing part, and
the second reverse surface is exposed from the second sealing part.

19. The semiconductor device according to claim 1, wherein the first semiconductor element is a switching element,
the second semiconductor element is a control element,
the first electrode is a source,
the second electrode is a drain,
the third electrode is a gate, and
the second semiconductor element is electrically connected to the third electrode via the wiring layer.
